(19) United States
(12) Patent Application Publication
(10) Pub. No.: US 2026/0293109 A1
(43) Pub. Date: Sep. 24, 2026

(54) THREE-DIMENSIONAL SEMICONDUCTOR DEVICES AND MANUFACTURING METHODS THEREOF

(71) Applicant: Yangtze Memory Technologies Holding Co., Ltd., Wuhan (CN)

(72) Inventors: Changzhi SUN, Wuhan (CN); Lujia OUYANG, Wuhan (CN); Zhiliang XIA, Wuhan (CN)

(21) Appl. No.: 19/250,893

(22) Filed: Jun. 26, 2025

Related U.S. Application Data
(63) Continuation of application No. PCT/CN2025/083104, filed on Mar. 18, 2025.

(51) Int. Cl. H10B 12/00; H10D 1/68

(52) U.S. Cl. CPC H10B 12/482; H10B 12/03; H10B 12/485; H10D 1/714

(57) ABSTRACT

Systems, devices, and manufacturing methods for a semiconductor device are provided. In one aspect, a semiconductor device includes a stack of insulating layers and memory layers alternating with each other. A memory layer includes: a memory cell and a bit line (BL). The memory cell includes a semiconductor body having a first end and a second end, and a capacitor structure adjacent to the semiconductor body. The capacitor structure includes a first electrode that extends along the second direction and is coupled to the second end of the semiconductor body. The BL is coupled to the first end of the semiconductor body. The semiconductor device further includes a gate structure extending in the stack and being at least partially surrounded by the semiconductor body.

### TECHNICAL FIELD

The present disclosure relates to semiconductor devices and fabrication processes for semiconductor devices.

### BACKGROUND

Semiconductor devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for managing three-dimensional (3D) semiconductor devices.

One aspect of the present disclosure features a semiconductor device, including a stack of insulating layers and memory layers alternating with each other along a first direction, a memory layer of the memory layers includes: a memory cell including: a semiconductor body including a first end and a second end opposite to the first end along a second direction different from the first direction; and a capacitor structure adjacent to the semiconductor body along the second direction, the capacitor structure including a first electrode that extends along the second direction and is coupled to the second end of the semiconductor body; and a bit line (BL) coupled to the first end of the semiconductor body; and a gate structure extending in the stack along the first direction, the gate structure being at least partially surrounded by the semiconductor body.

In some implementations, the semiconductor device includes: a second electrode including: a first portion extending in the stack in the first direction; and a plurality of second portions spaced apart from one another along the first portion in the first direction, where a second portion of the plurality of second portions includes a first part and a second part on opposite sides of the first portion along the second direction, respectively, and the second portion extends in a corresponding memory layer of the memory layers along the second direction.

In some implementations, the memory cell is a first memory cell, the semiconductor body is a first semiconductor body, the capacitor structure is a first capacitor structure; the memory layer includes a second memory cell including a second semiconductor body coupled to the bit line and a second capacitor structure; and the first capacitor structure and the second capacitor structure are between the first semiconductor body and the second semiconductor body along the second direction.

In some implementations, the second capacitor structure includes a respective first electrode, the first electrode of each of the first capacitor structure and the second capacitor structure is coupled to the second electrode and is separated from the second electrode by a capacitor dielectric layer; and the first electrode of the first capacitor structure is at least partially surrounding the first part of a corresponding second portion of the plurality of second portions of the second electrode, and the first electrode of the second capacitor structure is at least partially surrounding the second part of the corresponding second portion of the plurality of second portions of the second electrode.

In some implementations, the semiconductor device includes: an isolation structure extending in the stack along the first direction and the second direction, where the memory cell is a first memory cell, the memory layer includes a third memory cell adjacent to the first memory cell along a third direction different from the first direction and the second direction, the first memory cell and the third memory cell are separated by the isolation structure along the third direction, and the third memory cell includes a third semiconductor body and a third capacitor structure.

In some implementations, the first portion of the second electrode extends through the isolation structure along the third direction, the second portion of the plurality of second portions of the second electrode further includes a third part and a fourth part on opposite sides of the first portion along the second direction, respectively, the third part is adjacent to the first part and separated from the first part by the isolation structure along the third direction, and the fourth part is adjacent to the second part and separated from the second part by the isolation structure along the third direction, and the third capacitor structure includes a respective first electrode coupled to the second electrode, and the first electrode of the third capacitor structure is at least partially surrounding the third part of the second portion of the plurality of second portions of the second electrode.

In some implementations, the memory layer is a first memory layer, the memory cell is a first memory cell, and the capacitor structure is a first capacitor structure; the memory layers include a second memory layer, the second memory layer includes a fourth memory cell adjacent to the first memory cell along the first direction, and the fourth memory cell includes a fourth capacitor structure; and each of the first capacitor structure and the fourth capacitor structure includes a first electrode coupled to a corresponding second portion of the plurality of second portions of the second electrode.

In some implementations, the bit line includes a first segment extending along a third direction different from the first direction and the second direction.

In some implementations, the bit line includes at least one of: a second segment extending along the second direction and being coupled to a first end of the first segment; or a third segment extending along the second direction and being coupled to a second end of the first segment, the second end of the first segment being opposite to the first end of the first segment along the third direction.

In some implementations, the semiconductor device includes a BL contact structure extending in the stack along the first direction; and where the BL contact structure is in contact with one of the first segment, the second segment or the third segment of the bit line.

In some implementations, the BL contact structure is a first BL contact structure, the semiconductor device includes a plurality of BL contact structures including the first BL contact structure and a second BL contact structure; the second segment includes a first end coupled to the first end of the first segment, the third segment includes a first end coupled to the second end of the first segment and a second end opposite to the first end of the third segment along the second direction; and the first BL contact structure is in contact with the first end of the second segment, and the second BL contact structure is in contact with the second end of the third segment.

In some implementations, the gate structure includes: a first portion extending in the stack in the first direction; and a plurality of second portions spaced apart from one another along the first portion of the gate structure in the first direction, where a width of the first portion of the gate structure along a third direction different from the first direction and the second direction is smaller than a width of a second portion of the plurality of second portions of the gate structure along the third direction.

In some implementations, the gate structure includes: a first portion extending in the stack in the first direction; and a plurality of second portions spaced apart from one another along the first portion of the gate structure in the first direction, where a width of the first portion of the gate structure along the second direction is smaller than a width of a second portion of the plurality of second portions of the gate structure along the second direction.

In some implementations, the semiconductor body has a first width along the second direction and a second width along a third direction different from the first direction and the second direction, and the first width of the semiconductor body is greater than the second width of the semiconductor body.

In some implementations, the semiconductor body includes a metal oxide semiconductor material.

In some implementations, the semiconductor device includes a plurality of second electrodes including the second electrode, where first portions of adjacent second electrodes of the plurality of second electrodes that arranged along the third direction is separated by the isolation structure.

In some implementations, the semiconductor body of the memory cell includes two opposing walls along the first direction and a sidewall connecting the two opposite walls, the two opposing walls and the sidewall define an internal opening, where a corresponding second portion of the plurality of second portions of the gate structure is at least partially within the internal opening of the semiconductor body of the memory cell.

Another aspect of the present disclosure features a semiconductor device including: a stack of insulating layers and memory layers alternating with each other along a first direction, the memory layers including a first memory layer and a second memory layer, the first memory layer including a first memory cell and a second memory cell adjacent to the first memory cell along a second direction different from the first direction, the second memory layer including a third memory cell adjacent to the first memory cell along the first direction, where each of the first memory cell, the second memory cell and the third memory cell includes: a semiconductor body; and a capacitor structure adjacent to the semiconductor body along the second direction, the capacitor structure extending along the second direction and being coupled to the semiconductor body, the capacitor structure including a first electrode, where the capacitor structure of the first memory cell and the capacitor structure of the second memory cell are between the semiconductor body of the first memory cell and the semiconductor body of the second memory cell along the second direction; and a second electrode extending in the stack along the first direction and being coupled to the first electrode of each of first memory cell, the second memory cell and the third memory cell.

In some implementations, the first memory layer includes a first bit line (BL) coupled to the first memory cell and the second memory cell, and the second memory layer includes a second bit line coupled to the third memory cell; and the semiconductor device includes a plurality of BL contact structures extending in the stack at different depths, and the plurality of BL contact structures includes: a first BL contact structure coupled to the first bit line of the first memory layer; and a second BL contact structure coupled to the second bit line of the second memory layer.

In some implementations, the semiconductor device includes: a plurality of gate structures extending in the stack along the first direction, where the plurality of gate structures includes: a first gate structure at least partially surrounded by the semiconductor body of the first memory cell and the semiconductor body of the third memory cell; and a second gate structure at least partially surrounded by the semiconductor body of the second memory cell.

In some implementations, the capacitor structure of each of first memory cell, the second memory cell and the third memory cell comprises a capacitor dielectric layer in contact with the first electrode, and where the second electrode includes: a first portion extending in the stack in the first direction; and a plurality of second portions spaced apart from one another along the first portion in the first direction, the plurality of second portions includes an upper second portion and a lower second portion.

In some implementations, each of the upper second portion and the lower second portion includes a first part and a second part on opposite sides of the first portion along the second direction, respectively, and where the first electrode of the first memory cell is at least partially surrounding the first part of the lower second portion and separated from the first part of the lower second portion by the capacitor dielectric layer, where the first electrode of the second memory cell is at least partially surrounding the second part of the lower second portion and separated from the second part of the lower second portion by the capacitor dielectric layer, and where the first electrode of the third memory cell is at least partially surrounding the first part of the upper second portion and separated from the first part of the upper second portion by the capacitor dielectric layer.

Another aspect of the present disclosure features a method including: forming a stack of insulating layers and memory layers alternating with each other along a first direction, where a memory layer of the memory layers includes: a memory cell and a bit line (BL) coupled to the memory cell, the memory cell includes: a semiconductor body including a first end and a second end opposite to the first end along a second direction different from the first direction, and a capacitor structure adjacent to the semiconductor body along the second direction, the capacitor structure including a first electrode that extends along the second direction and is coupled to the second end of the semiconductor body, and the BL is coupled to the first end of the semiconductor body; and forming a gate structure extending in the stack along the first direction, the gate structure being at least partially surrounded by the semiconductor body.

In some implementations, the method includes: forming a second electrode, where the second electrode includes: a first portion extending in the stack in the first direction; and a plurality of second portions spaced apart from one another along the first portion in the first direction, and where a second portion of the plurality of second portions includes a first part and a second part on opposite sides of the first portion along the second direction, respectively, and the second portion extends in a corresponding memory layer of the memory layers along the second direction.

In some implementations, the memory layer is a first memory layer, the memory cell is a first memory cell, and the capacitor structure is a first capacitor structure, where forming the memory layers includes forming the first memory layer and a second memory layer, where forming the first memory layer includes forming the first memory cell and a second memory cell adjacent to the first memory cell along the second direction, the second memory cell including a second capacitor structure, where forming the second memory layer includes forming a third memory cell adjacent to the first memory cell along the first direction, the third memory cell including a third capacitor structure, each of the second capacitor structure and the third capacitor structure including a respective first electrode, and where forming the second electrode includes forming the second electrode such that the respective first electrode of each of the first memory cell, the second memory cell and the third memory cell is at least partially surrounding a corresponding second portion of the plurality of second portions of the second electrode.

In some implementations, the method includes forming a BL contact structure extending in the stack along the first direction, the BL contact structure being coupled to the bit line.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a schematic view of a cross-section of an example 3D memory device.

FIG. 1B illustrates a schematic view of a cross-section of another example 3D memory device.

FIG. 2A illustrates an isometric view of an example of a semiconductor device.

FIG. 2B illustrates a cross-sectional view of the semiconductor device of FIG. 2A along A-A′ axis.

FIG. 2C illustrates a cross-sectional view of the semiconductor device of FIG. 2A along B-B′ axis.

FIG. 2D illustrates a cross-sectional view of the semiconductor device of FIG. 2A along C-C′ axis.

FIG. 2E illustrates a cross-sectional view of a second electrode of a capacitor of the semiconductor device of FIG. 2A in X-Y plane.

FIG. 2F illustrates an enlarged view of a region of the cross-sectional view of FIG. 2C including a semiconductor body.

FIG. 2G illustrate a plan view of an example of a semiconductor device.

FIG. 3A illustrates an isometric view of another example of a semiconductor device.

FIG. 3B illustrates a cross-sectional view of the semiconductor device of FIG. 3A along A-A′ axis.

FIG. 3C illustrates a cross-sectional view of the semiconductor device of FIG. 3A along B-B′ axis.

FIG. 3D illustrates a cross-sectional view of the semiconductor device of FIG. 3A along C-C′ axis.

FIG. 3E illustrates a plan view of another example of a semiconductor device.

FIGS. 4A-4O illustrate views of an example of a semiconductor device during various stages of a manufacturing process.

FIGS. 5A-5E illustrate an example of process steps of forming a semiconductor body.

FIG. 6 illustrates a flow chart of a process of an example method of forming a semiconductor device.

FIG. 7 illustrates a block diagram of a system having one or more semiconductor devices.

Like reference numbers and designations in the various drawings indicate like elements. It is to be understood that the various exemplary implementations shown in the figures are merely illustrative representations and are not necessarily drawn to scale.

### DETAILED DESCRIPTION

As the scaling of planar DRAM is approaching its limits, 3D DRAM devices can be a promising solution to address the challenges of DRAM capacity and density. However, the fabrication of 3D DRAM remains highly complex. In some cases, silicon (Si) and/or silicon germanium (SiGe) epitaxial stacking can be used for forming semiconductor bodies in DRAM memory cells. However, these techniques can be constrained by limited stickability and low density. Additionally, Si-based channels can also suffer from high leakage currents and poor device reliability. A simplified manufacturing process (e.g., in terms of architectural design and material selection) to form a reliable memory device can be desired.

Implementations of the present disclosure provide semiconductor devices and methods for forming such semiconductor devices. In some implementations, a semiconductor device includes a stack of insulating layers and memory layers alternating with each other, a memory layer including: a memory cell that includes a semiconductor body having a first end and a second end; and a capacitor adjacent to the semiconductor body, where the capacitor includes a first electrode that extends along the second direction and is coupled to the second end of the semiconductor body; and a bit line (BL) coupled to the first end of the semiconductor body. The semiconductor device includes a BL contact structure extending in the stack and being coupled to the bit line; and a gate structure extending in the stack and being at least partially surrounded by the semiconductor body.

Implementations of the present disclosure can provide one or more of the following technical advantages and/or benefits. First, the techniques implemented herein can simply the manufacturing process flow, thereby reducing manufacture cost. For example, the example implementations of the semiconductor devices can include horizontally arranged DRAM cells (e.g., 1T1C cell, 2T1C cell, 3T1C cell, etc.) where the capacitor extends along a lateral direction, and the semiconductor bodies can have a channel-all-around (CAA) configuration. The capacitors can be formed by recessing horizontal openings in conductive layers of a stack structure, thereby simplifying the manufacturing process. Similarly, the CAA configuration can also be formed through a simplified process, e.g., by recessing channel holes within the conductive layers of the stack structure, and then filling the center of the channel holes with gate structures.

Additionally, the techniques can reduce channel leakage, thereby improving device reliability. For example, in some implementations, the semiconductor body of the semiconductor devices can include a metal oxide semiconductor material, e.g., indium gallium zinc oxide (IGZO), or indium gallium silicon oxide (IGSO). Without being limited to any particular theory, IGZO or IGSO can have lower contact resistance, enhance channel performance with high electron mobility and reduce channel leakage.

Further, the techniques can improve sensing margin of the bit lines. For example, in some implementations, two or more BL contact structures can be formed to couple to the same BL, improving sensing margin issues of horizontal bit lines. Additionally, the two or more BL contact structures can be arranged in a symmetric manner to reduce contact resistance.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

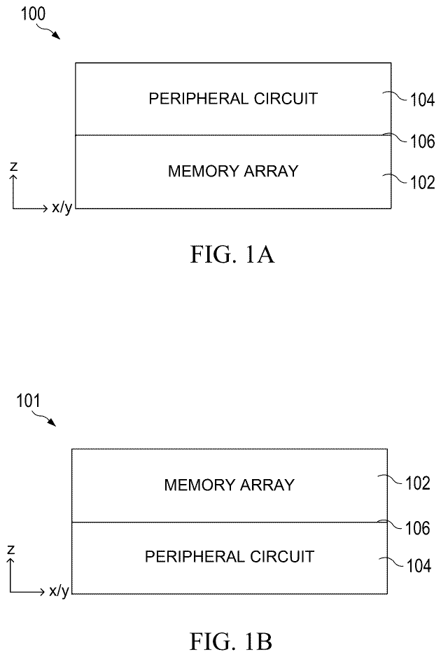

FIG. 1A illustrates a schematic view of a cross-section of an example 3D memory device 100, according to one or more implementations of the present disclosure. 3D memory device 100 represents an example of a bonded chip. The components of 3D memory device 100 (e.g., memory array and peripheral circuits) can be formed separately on different substrates and then jointed to form a bonded chip. 3D memory device 100 can include a first semiconductor structure 102 including an array of memory cells (e.g., memory array). In some implementations, the memory array includes an array of DRAM memory cells, NAND memory cells, or ferroelectric memory cells. For ease of description, a DRAM memory array may be used as an example for describing the memory array in the present disclosure.

The first semiconductor structure 102 can be a DRAM memory device in which memory cells are provided in the form of an array of DRAM memory cells. Memory cells can be organized into pages, which are then organized into blocks in which each memory cell is electrically coupled to a corresponding bit line (BL) and a corresponding word line (WL). In some implementations, a plane contains a certain number of blocks that are electrically connected through the same bit line. The first semiconductor structure 102 can include one or more planes, and the peripheral circuits that are needed to perform all the read/program (write)/erase operations can be included in a second semiconductor structure 104.

DRAM cell can be a 1T1C cell consisting of one transistor and one capacitor. It is understood that DRAM cell may be of any suitable configurations, such as 2T1C cell, 3T1C cell, etc. The transistor can be a MOSFET used to switch a respective DRAM cell. In some implementations, the transistor includes a semiconductor body (e.g., the active region in which a channel can form), and a gate structure coupled to the semiconductor body. In some implementations, the gate structure includes a gate electrode and a gate dielectric layer between the gate electrode and the semiconductor body. In some implementations, the gate dielectric layer abuts one side of the semiconductor body, and the gate electrode abuts the gate dielectric layer.

As shown in FIG. 1A, 3D memory device 100 can also include the second semiconductor structure 104 including the peripheral circuits of the memory array of the first semiconductor structure 102. The peripheral circuits (a.k.a. control and sensing circuits) can include any suitable digital, analog, and/or mixed-signal circuits used for facilitating the operations of the memory array. For example, the peripheral circuit can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in second semiconductor structure 104 use CMOS technology, e.g., which can be implemented with logic processes (e.g., technology nodes of 90 nm, 65 nm, 60 nm, 45 nm, 32 nm, 28 nm, etc.). As described above and below in detail, consistent with the scope of the present disclosure, the technology nodes used for fabricating the peripheral circuits in second semiconductor structure 104 can be above 22 nm in order to reduce leakage current, maintain certain voltage levels (e.g., 1.2 V and above), and reduce the cost.

As shown in FIG. 1A, 3D memory device 100 further includes a bonding interface 106 vertically (e.g., along Z direction) between first semiconductor structure 102 and second semiconductor structure 104. In some implementations, the first and the second semiconductor structures 102 and 104 can be fabricated separately (and in parallel in some implementations) such that the thermal budget of fabricating one of first and second semiconductor structures 102 and 104 does not limit the processes of fabricating another one of first and second semiconductor structures 102 and 104. Moreover, a large number of interconnects can be formed through bonding interface 106 to make direct, short-distance (e.g., micron-level) electrical connections between first semiconductor structure 102 and second semiconductor structure 104, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between the memory array in first semiconductor structure 102 and the peripheral circuits in second semiconductor structure 104 can be performed through the interconnects across the bonding interface 106. By vertically (e.g., along Z direction) integrating first and second semiconductor structures 102 and 104, the chip size can be reduced, and the memory cell density can be increased.

It is understood that the relative positions of stacked first and second semiconductor structures 102 and 104 are not limited. FIG. 1B illustrates a schematic view of a cross-section of an example 3D memory device 101, according to one or more implementations of the present disclosure. Different from 3D memory device 100 of FIG. 1A in which second semiconductor structure 104 including the peripheral circuits is above first semiconductor structure 102 including the memory array, in 3D memory device 101 of FIG. 1B, first semiconductor structure 102 including the memory array is above second semiconductor structure 104 including the peripheral circuits. Nevertheless, bonding interface 106 is formed vertically between first and second semiconductor structures 102 and 104 in 3D memory device 101, and first and second semiconductor structures 102 and 104 are jointed vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., Cu-to-Cu) bonding and dielectric-dielectric (e.g., SiO₂-to-SiO₂) bonding simultaneously. Data transfer between the memory array in first semiconductor structure 102 and the peripheral circuits in second semiconductor structure 104 can be performed through the interconnects across bonding interface 106. In some implementations, the bonding interface 106 can include a first bonding layer in the first semiconductor structure 102 and a second bonding layer in the second semiconductor structure 104. The first bonding layer can include first conductive structures isolated by a first isolating material (e.g., SiO₂ or other dielectric material). The second bonding layer can include second conductive structures isolated by a second isolating material (e.g., SiO₂ or other dielectric material). The first isolating material and the second isolating material can be same or different, e.g., according to actual fabrication needs. Each of the second conductive structures can correspond to a first conductive structure of the first conductive structures. As such, when the first semiconductor structure 102 and the second semiconductor structure 104 are stacked together, the second conductive structures can be in contact with the corresponding first conductive structures to form conductive bonding (e.g., metal-to-metal bonding) through the bonding interface 106.

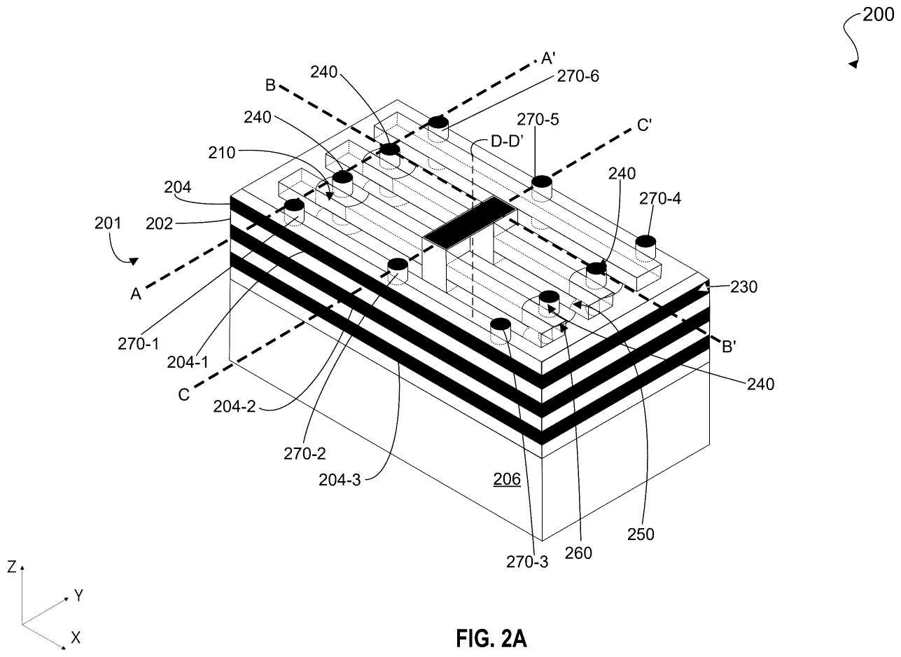

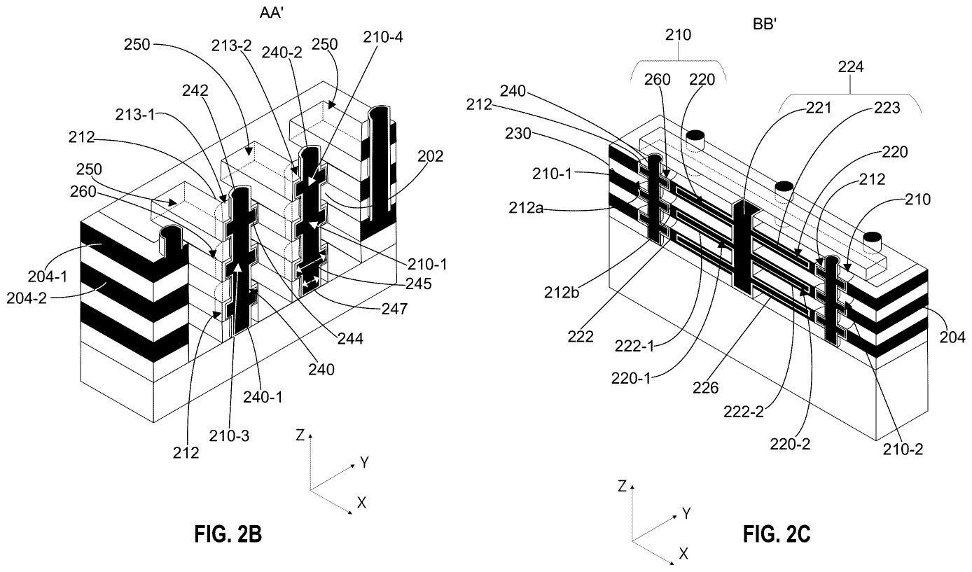

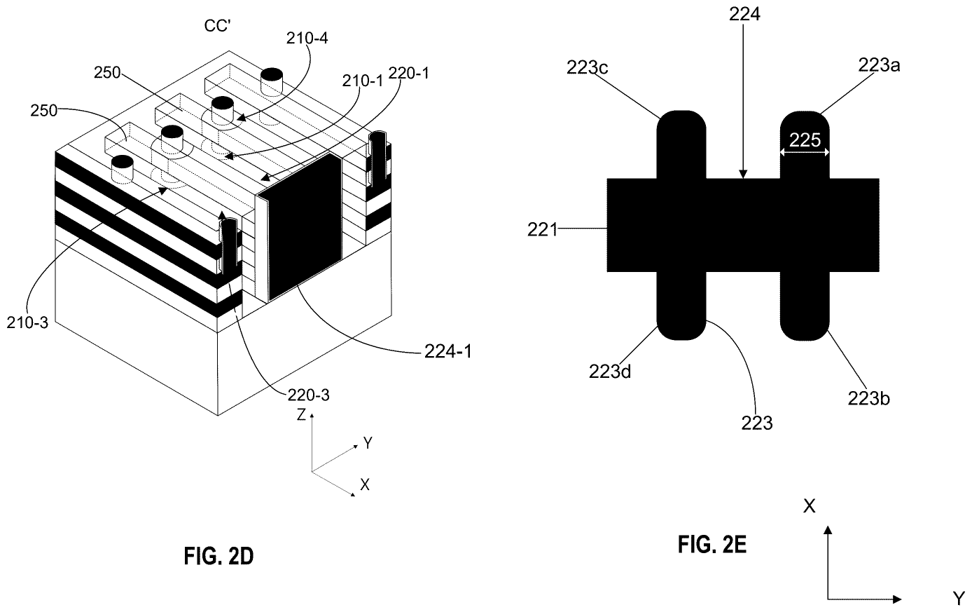

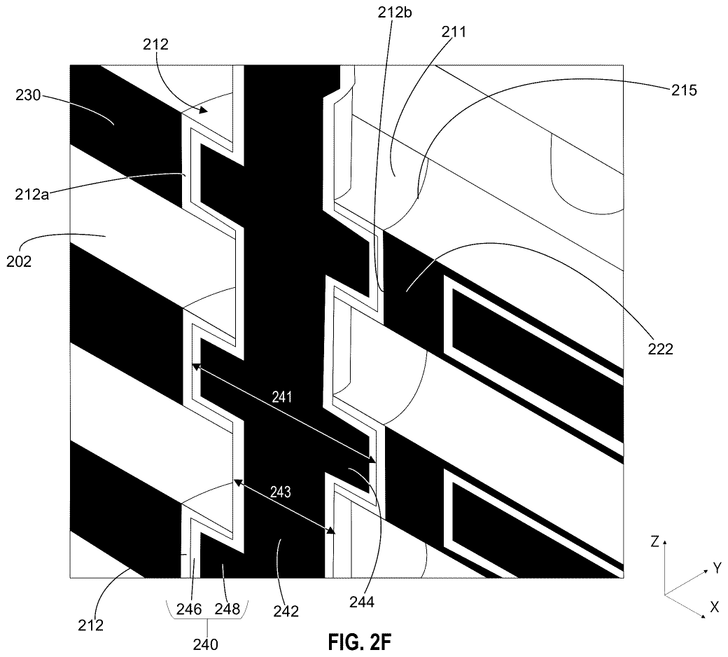

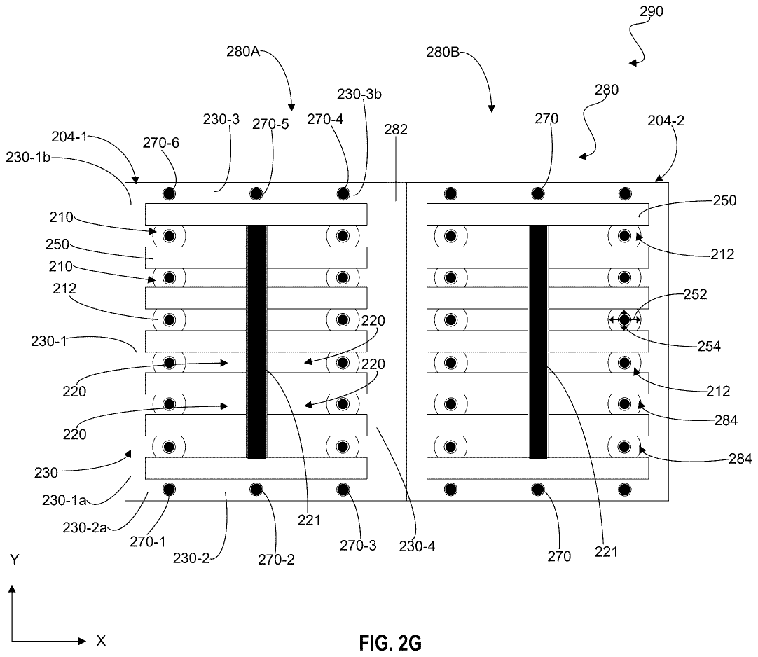

FIGS. 2A-2F illustrate an example of a semiconductor device 200 according to one or more implementations of the present disclosure. FIG. 2A illustrates an isometric view of the semiconductor device 200. FIG. 2B illustrates a cross-sectional view of the semiconductor device 200 along A-A′ axis of FIG. 2A. FIG. 2C illustrates a cross-sectional view of the semiconductor device 200 along B-B′ axis of FIG. 2A. FIG. 2D illustrates a cross-sectional view of the semiconductor device 200 along C-C′ axis of FIG. 2A. FIG. 2E illustrates a cross-sectional view of a second electrode of a capacitor of the semiconductor device 200 in X-Y plane. FIG. 2F illustrates an enlarged view of a region of the cross-sectional view of FIG. 2C including a semiconductor body. FIG. 2G illustrate a plan view of a semiconductor device 290 that is similar to the semiconductor device 200. The semiconductor device 290 differs from the semiconductor device 200 primarily in the number of memory cells 210 in each memory layer 204 and the length of second electrode 224 of capacitors 220 along Y direction. The semiconductor device 200, 290 can be the first semiconductor structure 102 of FIGS. 1A and 1B. For ease of description, reference will be made to FIGS. 2A-2G when describing the structure of the semiconductor device 200.

It is noted that X, Y, and Z axes (also referred to as X, Y, and Z directions) are included in FIGS. 2A-2G to further illustrate the spatial relationship of various components in a semiconductor device 200. A substrate of the semiconductor device 200 can include two lateral surfaces extending laterally in the X-Y plane: a top surface on the front side of the substrate on which a component of the semiconductor device 200 can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device 200 is determined relative to the substrate of the semiconductor device 200 in the Z direction (the vertical direction perpendicular to the X-Y plane, e.g., the thickness direction of the substrate) when the substrate is positioned in the lowest plane of the semiconductor device 200 in the Z direction. The same notion for describing the spatial relationships is applied throughout the present disclosure. The Z direction can be referred to as a vertical direction that is perpendicular to the top surface of the substrate, while X and/or Y direction can be referred to as a lateral direction that is parallel to the top surface of the substrate.

As illustrated in FIG. 2A, the semiconductor device 200 can include a stack 201 of insulating layers 202 and memory layers 204 alternating with each other along a first direction that is perpendicular to the top surface of the substrate 206 (e.g., Z direction). The insulating layers 202 can include dielectric materials including, but not limited to, silicon oxide, silicon nitride, silicon oxynitride, or any combination thereof. In some implementations, the stack 201 is on a substrate 206. The substrate 206 can include a wide array of semiconductor materials, such as silicon, germanium, gallium arsenide, indium phosphide, etc. In some implementations, the semiconductor device 200 does not include the substrate 206.

In some implementations, referring to FIGS. 2A and 2C, a memory layer 204 includes at least one memory cell 210. For example, the example semiconductor device 200 shown in FIG. 2C illustrates two memory cells 210 in one memory layer 204. A memory cell 210 can include a transistor 260 and a capacitor 220 that are horizontally arranged along a lateral direction (e.g., X direction). The transistor 260 can include a CAA configuration where a semiconductor body 212 can extend horizontally and at least partially surround a corresponding gate structure 240 that extends vertically. A single gate structure 240 can be surrounded by multiple semiconductor bodies 212 that are spaced from one another along Z direction in different memory layers 204.

The capacitor 220 can extend horizontally along a lateral direction (e.g., X direction) and couple to the transistor 260. The capacitor 220 can include a first electrode 222 and a second electrode 224. A plurality of capacitors 220 can share the same second electrode 224. The first electrode 222 of each capacitor 220 can extend horizontally within the corresponding memory layer 204. The second electrode 224 of the capacitors 220 can extend vertically in the stack 201 along Z direction and couple to a plurality of first electrodes 222. At least the first electrode 222 can also be referred to as a capacitor structure in the present disclosure.

A plurality of bit lines 230 can each extend horizontally within the corresponding memory layer 204, and adjacent bit lines 230 can be stacked along Z direction. In some implementations, each bit line 230 is coupled to all memory cells 210 in the corresponding memory layer 204.

The semiconductor device 200 can further include one or more isolation structures 250 that extend through the stack 201 vertically (e.g., along Z direction) and laterally (e.g., along X direction). The isolation structures 250 can be configured to isolate adjacent memory cells 210 along a lateral direction (e.g., Y direction) that is perpendicular to the longitudinal axis of the isolation structure 250.

Each component of the semiconductor device 200 mentioned above will be described in greater detail below in reference to FIGS. 2A-2G.

Referring now to FIGS. 2B, 2C and 2F for illustration of semiconductor bodies 212, the stack 201 can include multiple semiconductor bodies 212. The multiple semiconductor bodies 212 can be arranged in one or more groups. Each group can include one or more vertically stacked semiconductor bodies 212 that are penetrated by the same gate structure 240. Different groups of semiconductor bodies 212 can be arranged adjacent to one another along lateral directions (e.g., X or Y direction). For example, as illustrated in FIG. 2B, the semiconductor bodies 212 can include a first group 213-1 of semiconductor bodies 212 and a second group 213-2 of semiconductor bodies 212. In the example implementations illustrated in FIG. 2B, the first group 213-1 of the semiconductor bodies 212 includes three semiconductor bodies 212 that are stacked along Z direction and penetrated by a same gate structure 240 (e.g., the first gate structure 240-1). Similarly, the second group 213-2 of the semiconductor bodies 212 includes three semiconductor bodies 212 that are stacked along Z direction and penetrated by a same gate structure 240 (e.g., the second gate structure 240-2). The first group 213-1 of the semiconductor bodies 212 can be adjacent to the second group 213-2 of the semiconductor bodies 212 along Y direction.

As illustrated in FIGS. 2C and 2F, a semiconductor body 212 can include a first end 212a and a second end 212b opposite to the first end 212a along a lateral direction (e.g., X direction). For example, the second end 212b of the semiconductor body 212 can be a source terminal that is coupled to the capacitor 220, while the first end 212a of the semiconductor body 212 can be a drain terminal that is coupled to the BL 230. In some implementations, as shown in FIG. 2F, the semiconductor body 212 can have a “shell” shape. For example, the semiconductor body 212 can have two opposing walls, and the two opposing walls include two flat, exterior surfaces (e.g., a upper surface 211 and a lower surface) and interior surfaces. The two flat, exterior surfaces can be respectively in contact with upper and lower insulating layers 202. The interior surfaces can be in contact with a gate dielectric layer 246. The semiconductor body 212 can include two curved, exterior sidewalls 215 that are connected to each other. The two opposing walls and the sidewall can define an internal opening, thereby forming a “shell” shape. The two curved, exterior sidewalls 215 can be respectively in contact with the bit line 230 and the first electrode 222 of the corresponding capacitor 220.

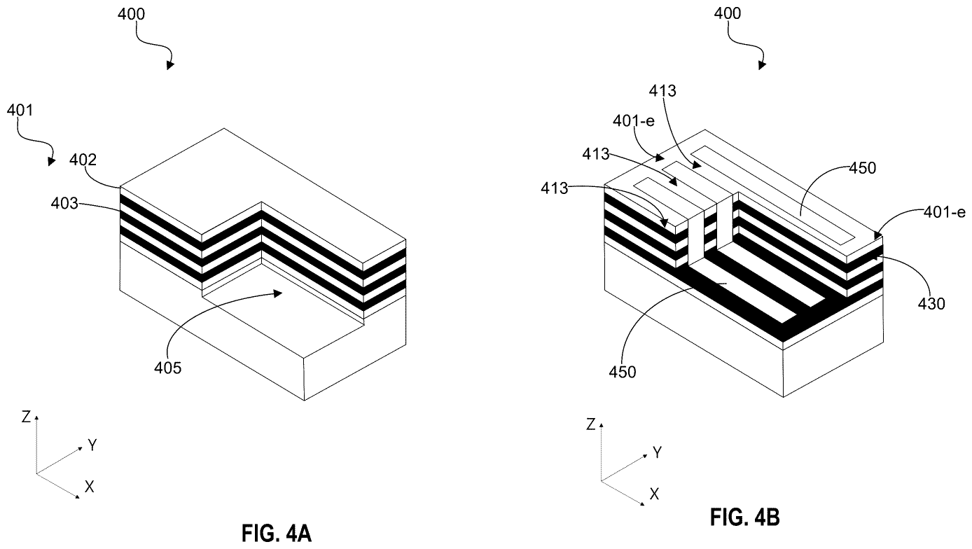

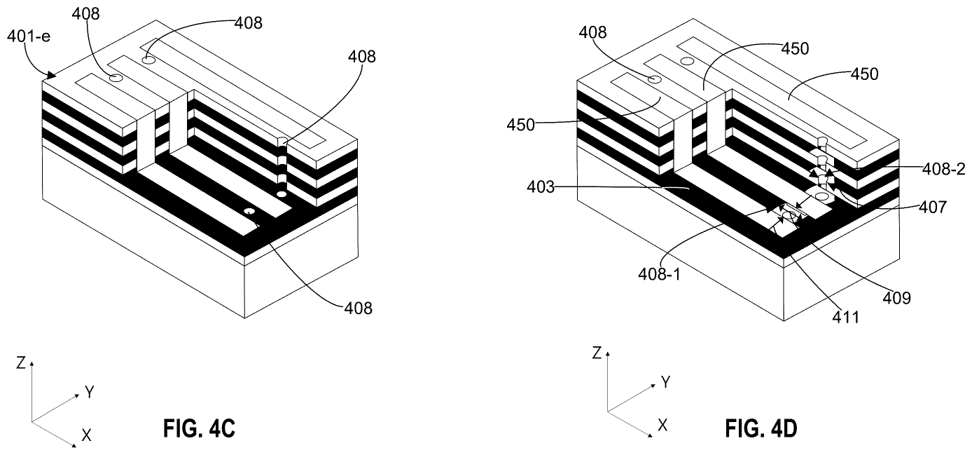

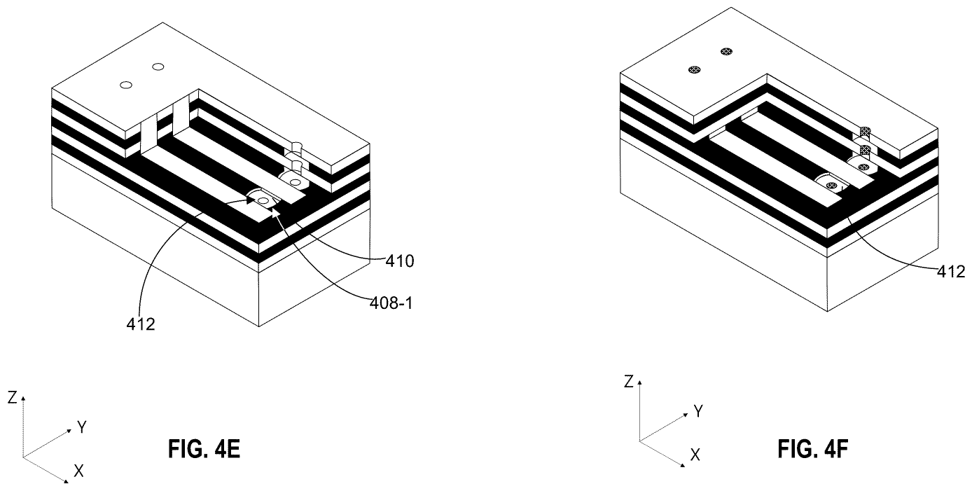

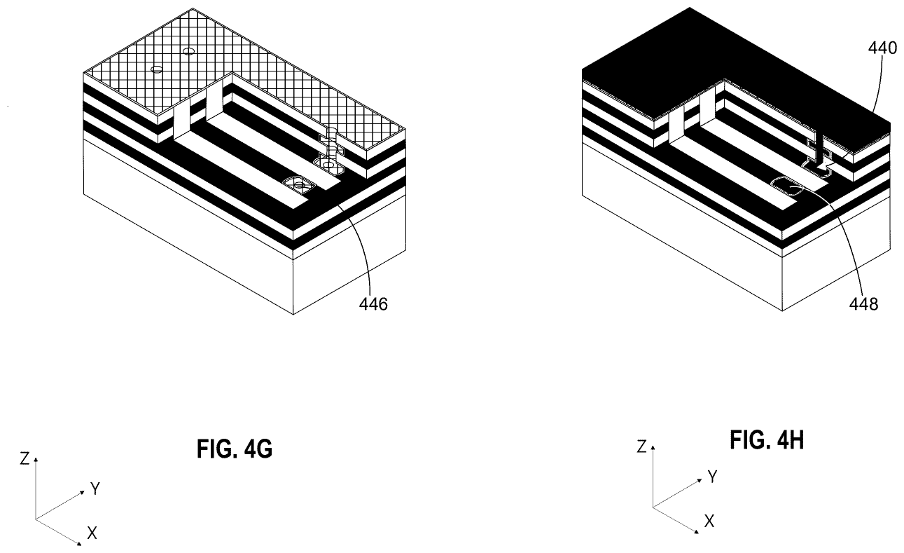

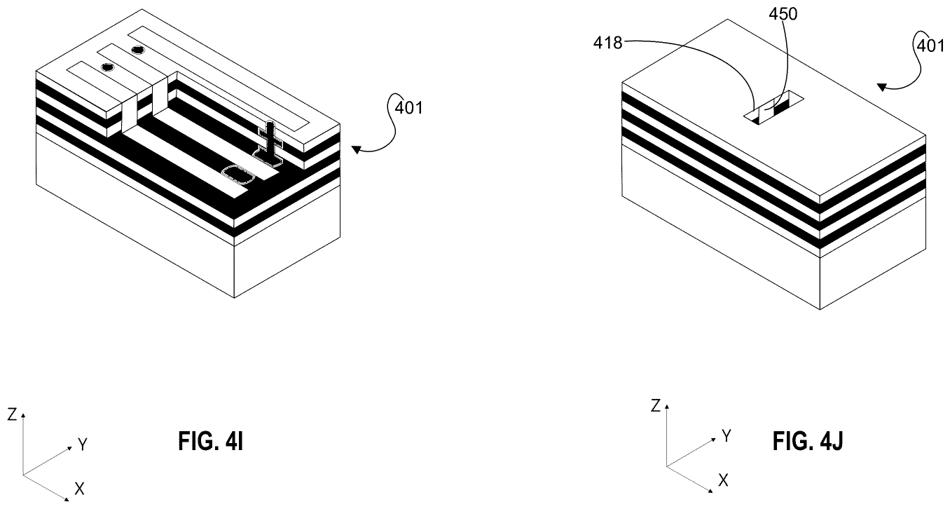

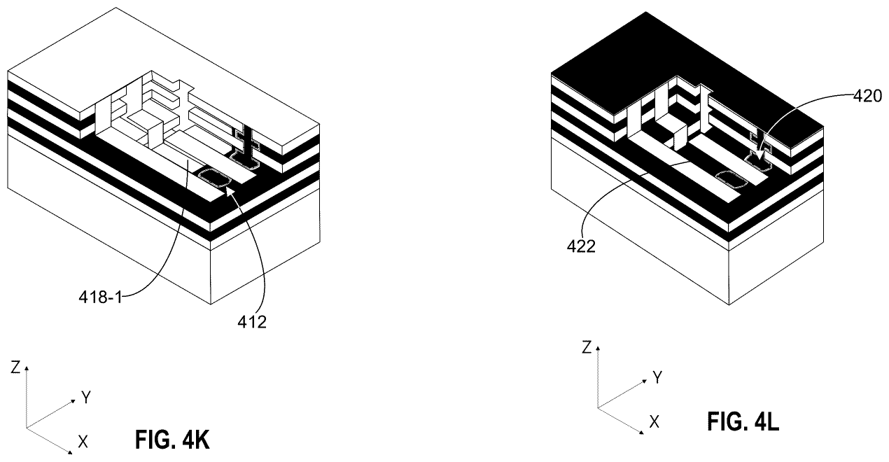

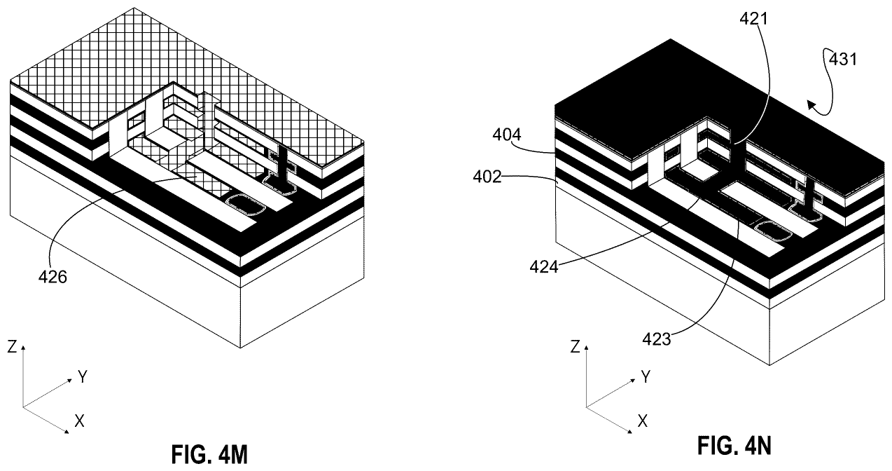

Turning briefly to FIG. 2G, the semiconductor body 212 has a first width 252 along the X direction and a second width 254 along another lateral direction (e.g., Y direction), and the first width 252 of the semiconductor body 212 can be greater than the second width 254 of the semiconductor body 212. X direction can be the lateral direction along which the isolation structure 250 extends, while Y direction can be the lateral direction that is perpendicular to the X direction. As described in greater detail below in reference to FIGS. 4A-4O, this dimension difference can result from the formation of the channel hole, where its dimension along Y direction can be constrained by the presence of the isolation structures 450.

In some implementations, the semiconductor body 212 includes a metal oxide semiconductor material. For example, the semiconductor body 212 can include indium gallium zinc oxide (IGZO), or indium gallium silicon oxide (IGSO). Without being limited to any particular theory, IGZO or IGSO can enhance channel performance with high electron mobility and reduced leakage due to wider bandgap, lower defect density, and/or improved interface quality between the IGZO or IGSO and the gate dielectric layer 246.

Referring now to FIGS. 2A, 2B and 2F for illustration of gate structures 240, a plurality of gate structures 240 can extend vertically through the stack 201 along Z direction. As noted above, each gate structure 240 can extend through a corresponding group of semiconductor bodies 212 that has one or more semiconductor bodies 212 vertically stacked along Z direction. In some implementations, the gate structure 240 extends through center regions of the corresponding semiconductor bodies 212. In some implementations, as illustrated in FIGS. 2A and 2B, each gate structure 240 is between two adjacent isolation structures 250, and the gate structure 240 may not extend across the isolation structure 250 along Y direction.

With continued reference to FIG. 2B, the gate structure 240 can include a first portion 242 extending vertically in the stack 201 in the Z direction and a plurality of second portions 244 surrounding the first portion 242 and spaced apart from one another in a linear sequence in the Z direction. The second portions 244 of the gate structure 240 can laterally extend within corresponding memory layers 204. Each second portion 244 can be at least partially covered by a corresponding semiconductor body 212. For example, as noted above, in some examples, the semiconductor body 212 can have a “shell” shape, and the second portions 244 of the gate structure 240 can be inside the interior space of the corresponding “shell”-shaped semiconductor bodies 212.

In some implementations, as illustrated in FIG. 2B, a width 247 of the first portion 242 of the gate structure 240 along Y direction is smaller than a width 245 of the second portion 244 of the gate structure 240 along Y direction. Although not shown, it is to be understood that, in some implementations, the width 247 of the first portion 242 of the gate structure 240 along Y direction can be equal to the width 245 of the second portion 244 of the gate structure 240 along Y direction. For example, both can be substantially equal to the spacing distance between adjacent isolation structures 250 minus the thickness of the semiconductor body 212. In some implementations, as illustrated in FIG. 2F, a width 243 of the first portion 242 of the gate structure 240 along the X direction is smaller than a width 241 of the second portion 244 of the gate structure 240 along the X direction.

In some implementations, with continued reference to FIG. 2F, the gate structure 240 includes a gate dielectric layer 246 and a gate electrode 248. The gate dielectric layer 246 can be in contact with the semiconductor body 212 and separate the semiconductor body 212 from the gate electrode 248. In some implementations, the gate dielectric layer 246 is a thin layer (e.g., a few nanometer) on the sidewall of a gate structure trench (e.g., the transistor hole 408 of FIG. 4D), and the gate electrode 248 fills the remaining space of the gate structure trench, as shown in FIG. 2F. In some implementations, the gate dielectric layer 246 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode 248 includes a conductive material including, but not limited to W, Co, Cu, Al, TiN, TaN, polysilicon, silicide, or any combination thereof. In some implementations, the gate electrode 248 includes multiple conductive layers, such as a W layer over a TiN layer.

Now turning to FIGS. 2C, 2D and 2E for illustration of capacitors 220, a plurality of capacitors 220 can be arranged in memory layers 204 and coupled to corresponding transistors 260. A capacitor 220 can include a first electrode 222, a second electrode 224 and a capacitor dielectric layer 226 in between. The first electrode 222 can extend along the X direction and be coupled to the second end 212b of the semiconductor body 212. Similar to the semiconductor body 212, in some examples, the first electrode 222 can have a “shell” shape. For example, the “shell” shaped first electrode 222 can have flat top and bottom exterior surfaces respectively in contact with corresponding upper and lower insulating layers 202 and interior surfaces in contact with the capacitor dielectric layer 226. The first electrode 222 can also include an exterior sidewall that is coupled to the second end 212b of the semiconductor body 212. However, different from the “shell” shape of the semiconductor body 212, the first electrode 222 of each capacitor 220 is positioned on only one side of a first portion 221 of the second electrode 224. For example, referring to FIG. 2C, the first electrode 222-1 of a first memory cell 210-1 and the first electrode 222-2 of a second memory cell 210-2 can be positioned on opposite sides of the first portion 221 of the second electrode 224 along X direction, and the first electrodes 222-1, 222-2 are not connected to each other.

The second electrode 224 of the capacitor 220 can include a first portion 221 extending vertically in the stack 201 in the Z direction and a plurality of second portions 223 spaced apart from one another. As illustrated in FIG. 2E which shows a cross-sectional view of the second electrode 224 of the capacitor 220 in the X-Y plane, the second portion 223 of the second electrode 224 can include a first part 223a and a second part 223b on opposite sides of the first portion 221 along the X direction, respectively. The first part 223a and the second part 223b can extend laterally within a same memory layer 204 away from the first portion 221 of the second electrode 224.

In some implementations, unlike the gate structure 240, the second electrode 224 extends across one or more isolation structures 250 along Y direction, as illustrated in FIGS. 2A and 2D. Therefore, the second electrode 224 can be shared by the memory cells 210 that are adjacent to one another along the Y direction. Referring to FIG. 2E, the second portion 223 of the second electrode 224 can further include a third part 223c and a fourth part 223d on opposite sides of the first portion 242 along the X direction, respectively. The third part 223c can be adjacent to the first part 223a and separated from the first part 223a by the isolation structure 250 (e.g., as illustrated in FIG. 2D) along the Y direction, and the fourth part 223d can be adjacent to the second part 223b and separated from the second part 223b by the same isolation structure 250 along the Y direction.

Each part of the second portion 223 of the second electrode 224 can be coupled to a same capacitor dielectric layer 226 but to a distinct first electrode 222, forming individual capacitors 220. For example, referring to FIG. 2C, the first part 223a of the second portion 223 of the second electrode 224 can be coupled to the first electrode 222-1 to form a first capacitor 220-1, while the second part 223b of the second portion 223 of the second electrode 224 can be coupled to the first electrode 222-2 to form a second capacitor 220-2. Similarly, the third part 223c and the fourth part 223d of the second portion 223 of the second electrode 224 can be coupled to corresponding first electrodes 222 to form a third capacitor (e.g., the third capacitor 220-3 of FIG. 2D) and a fourth capacitor. The third capacitor 220 can be adjacent to the first capacitor 220-1 along Y direction (e.g., as illustrated in FIG. 2D), and the fourth capacitor can be adjacent to the second capacitor 220-2 along Y direction.

In some implementations, the capacitor dielectric layer 226 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, first electrode 222 and/or second electrode 224 include a conductive material including, but not limited to W, Co, Cu, Al, TiN, TaN, polysilicon, silicide, or any combination thereof. In some implementations, the first and/or second electrode 222, 224 include multiple conductive layers, such as a W layer over a TiN layer.

Now turning to FIGS. 2A and 2G for illustration of bit lines 230, each bit line 230 can extend laterally within a corresponding memory layer 204, and the plurality of bit line 230 can be vertically stacked along Z direction. Adjacent bit lines 230 can be separated by a corresponding insulating layer 202. Each bit line 230 can be coupled to the first ends 212a of the semiconductor bodies 212 that are in the same memory layer 204. In other words, each memory layer 204 can have one bit line 230.

In some implementations, as illustrated in FIG. 2G, the bit line 230 includes a first segment 230-1 extending along Y direction. The first segment 230-1 of the bit line 230 can be coupled to the corresponding semiconductor bodies 212 that are arranged adjacent to each other along Y direction. For example, the example implementation of the first segment 230-1 of the bit line 230 shown in FIG. 2G is coupled to six semiconductor bodies 212 arranged along Y direction.

In some implementations, the bit line 230 further includes at least one of: a second segment 230-2 extending along the X direction and being coupled to a first end 230-1a of the first segment 230-1; or a third segment 230-3 extending along the X direction and being coupled to a second end 230-1b of the first segment 230-1. The second end 230-1b of the first segment 230-1 is opposite to the first end 230-1a of the first segment 230-1 along the Y direction.

In some implementations, the bit line 230 further includes a fourth segment 230-4 that is parallel to the first segment 230-1 but located on the opposite end of the memory layer 204 along X direction. The fourth segment 230-4 can be coupled to the corresponding semiconductor bodies 212 that are arranged to each other along Y direction. For example, the example implementation of the fourth segment 230-4 of the bit line 230 shown in FIG. 2G is coupled to six semiconductor bodies 212 arranged along Y direction. The fourth segment 230-4 can be coupled to the first segment 230-1 through at least one of the second and third segments 230-2, 230-3.

In some implementations, the bit line 230 has all four segments that form a rectangular shape. The bit line 230 can be positioned along the perimeter edge regions of the corresponding memory layer 204, as illustrated in FIG. 2G. As all four segments can be coupled to each other, all the memory cells 210 in the same memory layer 204 (e.g., twelve memory cells 210 in the memory layer 204-1 shown in FIG. 2G) can be coupled to the same bit line 230.

In some implementations, the bit line 230 is made of a conductive material including, but not limited to W, Co, Cu, Al, TiN, TaN, polysilicon, or any combination thereof. In some implementations, the bit line 230 is made of a composite conductive material that can be based on a metallic material (e.g., Ni, W, Co, Cu, Al) and a semiconductor material (e.g., Si). For example, the composite conductive material can include metal silicide, e.g., such as NiSi, WSi, CoSi, CuSi, AlSi, or any other suitable metal silicides having higher conductivities than doped silicon.

Continuing to reference FIGS. 2A and 2G for illustration of BL contact structures 270, the semiconductor device 200 can further include one or more BL contact structures 270. Each BL contact structure 270 can extend vertically in the stack 201 along the Z direction and terminate at different depths to couple to corresponding bit lines 230. In the example implementations shown in FIG. 2A, the stack 201 includes three memory layers, 204-1, 204-2, 204-3, and the semiconductor device 200 includes six BL contact structures, 270-1, . . . , 270-6. The first BL contact structure 270-1 and the fourth BL contact structure 270-4 can be terminated at the first memory layer 204-1 to connect to the bit line 230 in the first memory layer 204-1. The second BL contact structure 270-2 and the fifth BL contact structure 270-5 can be terminated at the second memory layer 204-2 to connect to the bit line 230 in the second memory layer 204-2. The third BL contact structure 270-3 and the sixth BL contact structure 270-6 can be terminated at the third memory layer 204-3 to connect to the bit line 230 in the third memory layer 204-3.

In some implementations, the BL contact structures 270 are in direct contact with the bit line 230. Therefore, the BL contact structures 270 can be located near perimeter regions of the memory layer 204, as illustrated in FIGS. 2A and 2G.

In some implementations, each bit line 230 is coupled to at least two BL contact structures 270. For example, as noted above, the first BL contact structure 270-1 and the fourth BL contact structure 270-4 can be both coupled to the first memory layer 204-1. Having two or more BL contact structures 270 couple to the same BL may improve sensing margin issues of horizontal bit lines 230.

In some implementations, referring to FIG. 2G, the first BL contact structure 270-1 can be in contact with first end 230-2a of the second segment 230-2 of the bit line 230 (e.g., near the corner of the first and second segments of the bit line 230), while the fourth BL contact structure 270 can be in contact with the second end 230-3b of the third segment 230-3 of the bit line 230 (e.g., near the corner of the third and fourth segments of the bit line 230). In other words, the first and fourth BL contact structures 270-1, 270-4 can be arranged symmetrically about a central vertical axis of the memory layer 204. For example, as illustrated in FIG. 2A, the first and fourth BL contact structures 270-1, 270-4 can be symmetrically arranged about the central axis D-D′ of the memory layer 204 (e.g., arranged diagonally). Similarly, the second and fifth BL contact structures 270-2, 270-5 can be symmetrically arranged about the central axis D-D′, and the third and sixth BL contact structures 270-3, 270-6 can be symmetrically arranged about the central axis D-D′. Without being limited to any particular theory, the symmetric arrangement may reduce the resistance of a combination of the bit line 230 and corresponding BL contact structures 270, thereby reducing energy loss.

It is to be understood that although FIGS. 2A and 2G show that the BL contact structures 270 can be arranged to be in contact with the second and third segments 230-2, 230-3 of the bit lines 230, in some implementations, the BL contact structures 270 can be arranged to be in contact with the first and fourth segments 230-1, 230-4 of the bit lines 230. In some implementations, the BL contact structures 270 are in contact with any one, any two, any three or all four segments of the bit lines 230.

In some implementations, a BL contact structure 270 includes a spacer layer and a conductive structure surrounded by the spacer layer. The spacer layer can isolate the conductive structure from other bit lines 230 as the BL contact structure 270 extends through the stack 201. The spacer layer can include dielectric materials including, but not limited to, silicon oxide, silicon nitride, silicon oxynitride, or any combination thereof. The conductive structure can include a conductive material including, but not limited to W, Co, Cu, Al, TiN, TaN, polysilicon, silicide, or any combination thereof. In some implementations, the conductive structure includes multiple conductive layers, such as a W layer over a TiN layer.

Referring now to FIGS. 2B, 2C and 2G for illustration of example arrangements of adjacent memory cells 210 along different directions, in some implementations, adjacent memory cells 210 (e.g., the first and second memory cells 210-1, 210-2) arranged along X direction (e.g., as illustrated in FIG. 2C) are symmetrically disposed on opposite sides of the first portion 221 of the second electrode 224 of the capacitors 220, with corresponding first electrodes 222 facing the first portion 221 of the second electrode 224. For example, the first electrode 222-1 of the first memory cell 210-1 can be located between its semiconductor body 212 and the first portion 221 of the second electrode 224. Similarly, the first electrode 222-2 of the second memory cell 210-2 can be located between its semiconductor body 212 and the first portion 221 of the second electrode 224. Therefore, the first capacitor 220-1 and the second capacitor 220-2 can be between the semiconductor body 212 of the first memory cell 210-1 and the semiconductor body 212 of the second memory cell 210-2 along the X direction.

As shown in FIGS. 2A and 2B, adjacent memory cells arranged along Y direction can be separated by a corresponding isolation structure 250. One or more isolation structures 250 can extend into the stack 201 vertically along Z direction and horizontally along X direction to isolate adjacent memory cells 210 arranged along Y direction. For example, as illustrated in FIG. 2B, the isolation structure 250 can isolate the first memory cell 210-1 from the third memory cell 210-3 along Y direction. The isolation structure 250 can include dielectric materials including, but not limited to, silicon oxide, silicon nitride, silicon oxynitride, or any combination thereof. In some implementations, the isolation structure 250 includes silicon nitride.

With continued reference to FIG. 2B, adjacent memory cells 210 arranged along Z direction can be separated by corresponding insulating layer 202. For example, the first memory cell 210-1 can be in the second memory layer 204-2. A fourth memory cell 210-4 that is adjacent to the first memory cell 210-1 along Z direction can be in the first memory layer 204-1. The first memory cell 210-1 can be separated from the fourth memory cell 210 by the insulating layer 202. However, as noted above, the first and fourth memory cell 210-1, 210-4 can be coupled to the same gate structure 240 (e.g., the gate structure 240-2 of FIG. 2B).

Referring now to FIG. 2G for illustration of multiple memory subarrays 280, the semiconductor device 290 can include two or more memory subarrays 280 (e.g., two subarrays 280A, 280B are shown in FIG. 2G). In some implementations, the subarrays 280 can be arranged adjacent to one another along lateral directions. For example, the first and second subarrays 280A, 280B are arranged along X direction. Although not shown, it is understood that adjacent subarrays 280 can also be arranged along Y direction, or along both X and Y directions.

The adjacent subarrays 280 can be separated and/or isolated by a separation structure 282. The separation structure 282 can extend through the stack 201 vertically along Z direction and laterally (e.g., along X and/or Y direction). The separation structure 282 can include dielectric materials including, but not limited to, silicon oxide, silicon nitride, silicon oxynitride, or any combination thereof.

As illustrated in FIG. 2G, in each subarray 280, a plurality of memory cells 210 can be arranged on opposite sides of the first portion 221 of the second electrode 224 of the capacitors 220. The example implementation in FIG. 2G shows, in each subarray 280, a single first portion 221 of the second electrode 224 of the capacitors 220 that extends across multiple isolation structures 250 along Y direction. Therefore, in this example implementation, all the memory cells 210 in each subarray can be coupled to the same second electrode 224. Additionally, as noted above, all the memory cells 210 in each subarray can be coupled to a same bit line 230.

Each subarray 280 can have a plurality of memory cell rows 284 arranged adjacent to each other along Y direction. For example, six memory cell rows 284 are illustrated in the example implementation of FIG. 2G in each subarray 280. Each memory cell row 284 can extend along X direction and include two memory cells 210 that are symmetrically arranged on opposite sides of the first portion 221 of the second electrode 224 of the capacitors 220.

It is to be understood that the example in FIG. 2G is for illustration purpose and is not intended to be construed in a limiting sense. For example, in some implementations, each subarray can include two or more first portions 221 of second electrodes 224 of the capacitors 220, the semiconductor device 290 can include three or more subarrays 280 that are arranged in an array along X and/or Y direction, and/or each memory cell row 284 can include three or more memory cells 210.

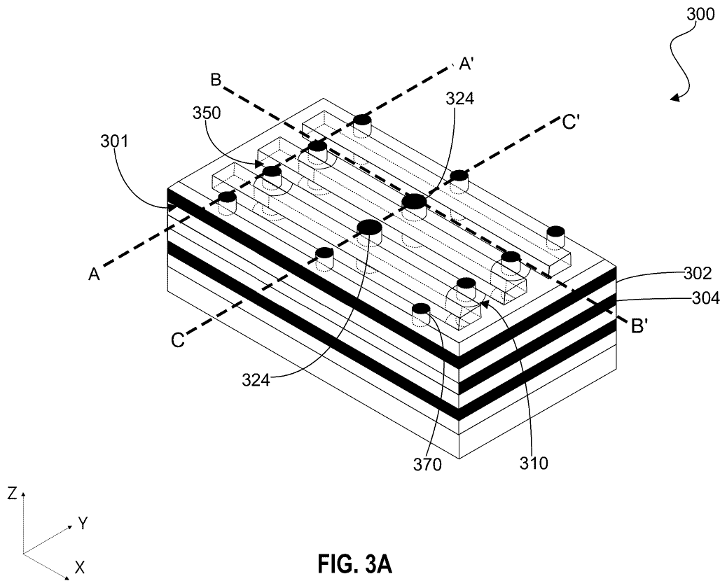

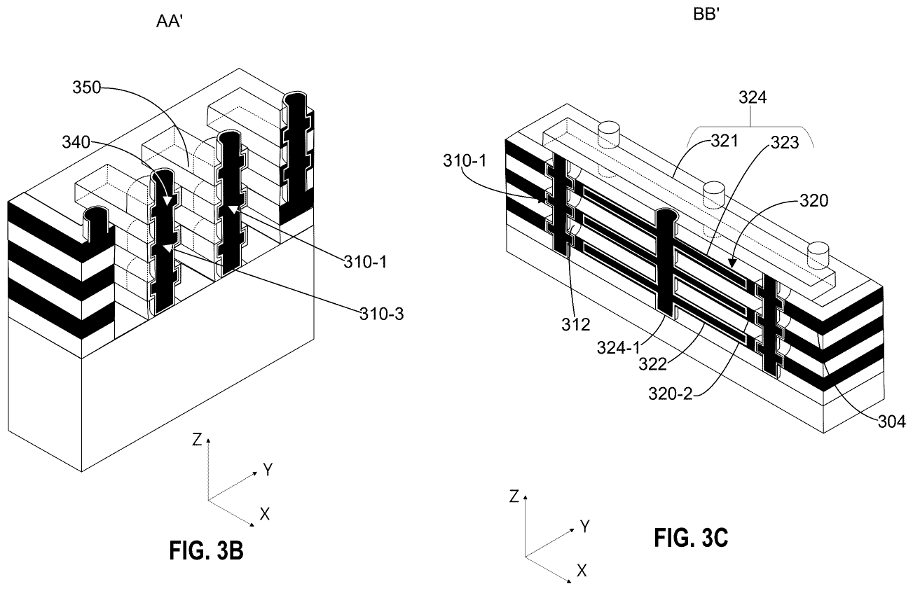

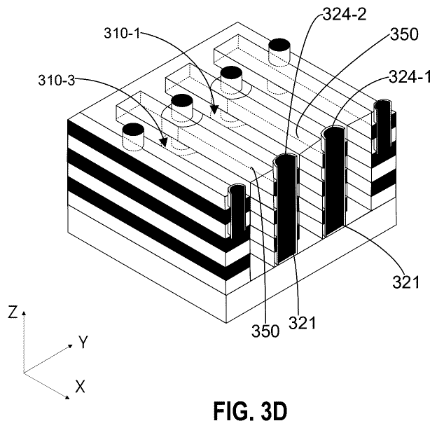

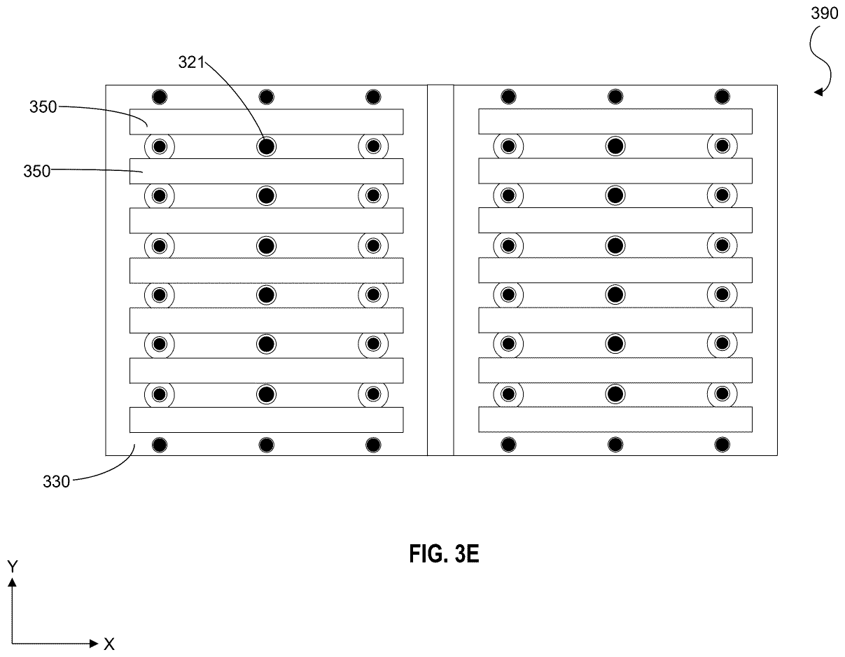

FIGS. 3A-3E illustrate another example of a semiconductor device 300 according to one or more implementations of the present disclosure. FIG. 3A illustrates an isometric view of the semiconductor device 300. FIG. 3B illustrates a cross-sectional view of the semiconductor device 300 along A-A′ axis of FIG. 3A. FIG. 3C illustrates a cross-sectional view of the semiconductor device 300 along B-B′ axis of FIG. 3A. FIG. 3D illustrates a cross-sectional view of the semiconductor device 300 along C-C′ axis of FIG. 3A. FIG. 3E illustrates a plan view of a semiconductor device 390 that is similar to the semiconductor device 300. The semiconductor device 300 differs from the semiconductor device 200 primarily in the structure of the first portion of the second electrode of the capacitors. The semiconductor device 390 differs from the semiconductor device 300 primarily in the number of memory cells 310 in each memory layer 304. Hereinafter, detailed descriptions of content overlapping with those of FIGS. 2A-2G will be omitted. For brevity, the following description will mainly focus on the differences between the semiconductor device 300 and the semiconductor device 200 described above.

As illustrated in FIG. 3C, similar to the second electrode 224 of the capacitors 220 of the semiconductor device 200, the second electrode 324 of the capacitors 320 of the semiconductor device 300 includes a first portion 321 extending vertically through the stack 301 along Z direction and a plurality of second portions 323 extending laterally within corresponding memory layers 304. However, different from that of the semiconductor device 200, the first portion 321 of the second electrode 324 of the semiconductor device 300 does not extend across any isolation structures 350, as illustrated in FIGS. 3A and 3D. Each first portion 321 of the second electrode 324 of the semiconductor device 300 can be positioned between adjacent isolation structures 350. As a result, each second electrode 324 of the capacitor 320 in the semiconductor device 300 can be coupled to the first electrodes 222 of corresponding memory cells 310 that are arranged only along X direction, but not along Y direction. For example, as illustrated in FIG. 3C, the second electrode 324-1 of the capacitor 320 can couple to the first electrodes 322 of both the first memory cell 310-1 and the second memory cell 310-2 that are arranged adjacent to each other along X direction. However, as illustrated in FIG. 3D, the first electrodes of the first memory cell 310-1 and the third memory cell 310 are not coupled to the same second electrode 324. Rather, the first electrode 322 of the capacitor 320 of the first memory cell 310-1 can be coupled to the second electrode 324-1, while the first electrode 322 of the capacitor 320 of the third memory cell 310-3 is coupled to another second electrode 324-2. As used herein, “coupled to” can include indirect contact or connection. In the semiconductor device 300, the second electrodes 324-1, 324-2 can be separated from each other by the isolation structure 350. In contrast, referring back to FIG. 2D, the first electrode 222 of the capacitor 220 can extend across at least one insolation structure 250 along Y direction, thereby coupling adjacent memory cells 210 that are arranged along Y direction together. Therefore, the first and third memory cells 210-1, 210-3 in the semiconductor device 200 can be coupled to the same second electrode 224 (e.g., the second electrode 224-1 of FIG. 2D).

In some implementations, as illustrated in FIG. 3E, a cross-section of the first portion 321 of the second electrode 324 in the semiconductor device 390 can have a circular shape. A size (e.g., a diameter) of the cross-section of the first portion 321 of the second electrode 324 in the semiconductor device 300 can be smaller than or equal to the spacing distance between adjacent isolation structures 350. In contrast, tuning briefly back to FIG. 2G, a cross-section of the first portion 221 of the second electrode 224 in the semiconductor device 290 can have a rectangular shape, and a size (e.g., a longitudinal length) of the cross-section of the first portion 221 of the second electrode 224 in the semiconductor device 290 can be greater than the spacing distance between adjacent isolation structures 250.

In some implementations, the plurality of second electrodes 324 of the capacitors 320 in the semiconductor device 300, 390 can be coupled together through a back end-of-line (BEOL) metal layer of the semiconductor device 300, 390. Therefore, the plurality of the second electrodes 324 of the capacitors 320 in the semiconductor device 300, 390 can be coupled to a same voltage level (e.g., a ground level).

FIGS. 4A-4O illustrate views of an example of a semiconductor device 400 during various stages of a manufacturing process. The example fabrication process is shown as being implemented with, e.g., the semiconductor device 200 described above with reference to FIGS. 2A-2G. However, the example fabrication process illustrated in FIGS. 4A-4O may be applicable with any other implementations of the semiconductor device described herein, e.g., the semiconductor device 290, 300, 390. For illustration purpose, the semiconductor device 400 in FIGS. 4A-4I and 4K-4N is shown with a cutaway view, where a portion of the semiconductor device 400 (e.g., the region 405 of FIG. 4A) is removed to reveal the inner structure details. It is to be understood in a real device, such cutaway region may not be present.

As illustrated in FIG. 4A, an initial stack 401 can be formed with insulating layers 402 and conductive layers 403 alternating with each other along a vertical direction (e.g., Z direction). The insulating layers 402 can be deposited using one or more thin film deposition techniques, including, but not limited to, chemical vapor deposition (CVD), physical vapor deposition (PVD), plasma enhanced chemical vapor deposition (PECVD) atomic layer deposition (ALD), sputtering, or any combination thereof. The conductive layers 403 can be deposited by one or more thin film deposition processes including, but not limited to, chemical vapor deposition (CVD), physical vapor deposition (PVD), atomic layer deposition (ALD), Metal-Organic Chemical Vapor Deposition (MOCVD), sputtering, electroplating, electroless plating, electron-beam evaporation, or any combination thereof.

As illustrated in FIG. 4B, at least one isolation structure 450 can be formed extending into the initial stack 401 vertically (e.g., along Z direction) and laterally (e.g., along X direction). In some implementations, a longitudinal length of the isolation structure 450 (e.g., along X direction) is smaller than the length of the initial stack 401 along the same direction such that the isolation structure 450 does not completely cut the initial stack 401 into isolated portions. Rather, different portions 413 of the initial stack 401 that are cut by the isolation structure 450 can be still connected at edge regions 401-e, as illustrated in FIG. 4B. The uncut conductive layers at the edge regions 401-e can be used as bit lines 430.

Forming the isolation structure 450 can involve an etching process to form an isolation trench followed by a deposition process. The isolation structure 450 can include dielectric materials including, but not limited to, silicon oxide, silicon nitride, silicon oxynitride, or any combination thereof. In some implementations, the isolation structure 450 includes silicon nitride. The etching can involve one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof. The dielectric material of the isolation structure 450 can be deposited using any one of the deposition techniques described herein, or any other suitable techniques.

As illustrated in FIG. 4C, transistor holes 408 can be formed extending through the initial stack 401 along Z direction. Each transistor hole 408 can be positioned between two adjacent isolation structures 450. In some implementations, a diameter of the transistor hole 408 is smaller than or equal to the spacing distance between adjacent isolation structures 450. In some implementations, the transistor holes 408 are formed adjacent to the edge regions 401-e of the initial stack 401, as shown in FIG. 4C. Forming the transistor holes 408 can involve one or more dry etching and/or wet etching techniques described herein.

As illustrated in FIG. 4D, some portions of the transistor holes 408 can be expanded by recessing parts of the conductive layers 403 that are surrounding the transistor holes 408. After expanding, the size 409 of the expanded portion 408-1 of the transistor hole 408 in the conductive layer 403 can be greater than the size 407 of the unexpanded portion 408-2 of the transistor hole 408 in the insulating layer 402. The expanded portions 408-1 of the transistor holes 408 can also be referred to as channel holes 408-1 in the present disclosure. In some implementations, due to the presence of isolation structures 450, the expansion of the channel holes 408-1 in the conductive layers 403 can be more restricted along the Y direction and less restricted along the X direction. As a result, the size 409 of the channel holes 408-1 along X direction can be greater than its size 411 along Y direction. Y direction can be the direction that is perpendicular to the longitudinal length of the isolation structures 450.

Expanding the transistor holes 408 can involve one or more dry etching and/or wet etching techniques described herein. The etchants can have metal-to-dielectric etch selectivity, where it preferentially etches the conductive layers 403 and does not significantly etch the insulating layers 402.

As illustrated in FIG. 4E, a channel material can be deposited into the transistor holes 408. The channel material can include a metal oxide semiconductor material. For example, the channel material can include indium gallium zinc oxide (IGZO), or indium gallium silicon oxide (IGSO). Without being limited to any particular theory, IGZO or IGSO can enhance channel performance with high electron mobility. The channel materials in the channel holes 408-1 can form the semiconductor body 412. In some implementations, the channel material forms a thin layer (e.g., a few nanometers) on the surfaces of the channel holes 408-1 rather than completely filling them. As noted above, in some examples, the semiconductor body 412 can have a “shell” shape. In some implementations, the deposition of channel material involves sputtering, pulsed laser deposition (PLD), atomic layer deposition (ALD), or any other deposition techniques described herein.

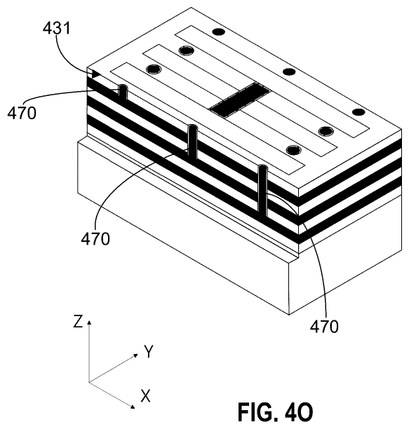

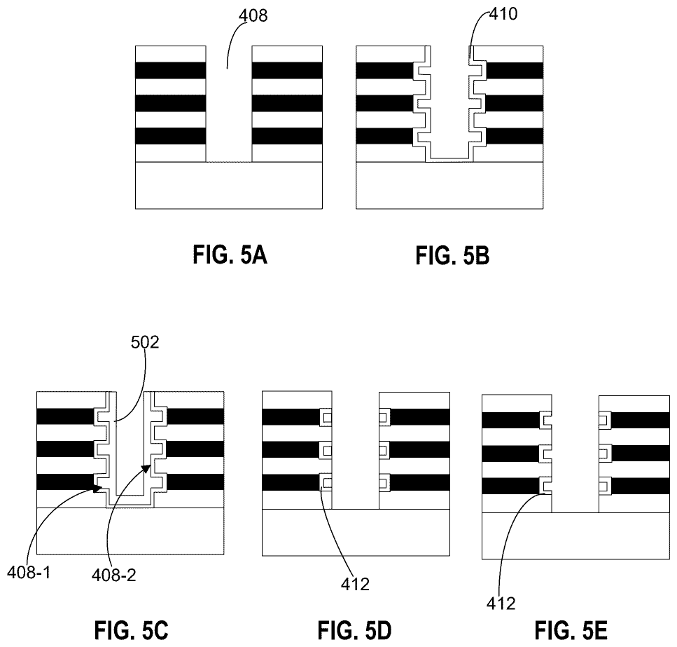

As illustrated in FIG. 4F, the channel material in the insulating layers 402 can be recessed to disconnect adjacent semiconductor bodies 412 along Z direction. Turning briefly to FIGS. 5A-5E, which illustrate more detailed process steps to form semiconductor bodies 412. FIGS. 5A and 5B show the process of depositing the channel material into the transistor holes 408, same as the process described above in reference to FIG. 4E. As illustrated in FIG. 5C, a sacrificial layer 502 can be deposited into the transistor holes 408. The sacrificial layer 502 can fill the remaining space of the channel holes 408-1, protecting the channel material inside the channel holes 408-1. Therefore, the thickness of the sacrificial layer 502 in the channel holes 408-1 can be greater than the thickness of the sacrificial layer 502 in the unexpanded portions of transistor holes 408-2. The sacrificial layer 502 an include dielectric materials including, but not limited to, silicon oxide, silicon nitride, silicon oxynitride, or any combination thereof. The sacrificial layer 502 can be formed by the deposition techniques described herein.

As illustrated in FIG. 5D, the sacrificial layer 502 can be etched by a uniform thickness across both the expanded portions 408-1 and unexpanded portions 408-2 of transistor holes 408. As the thickness of the sacrificial layer 502 in the channel holes 408-1 is greater, a portion of the sacrificial layer 502 can remain in the channel holes 408-1 after etching, while the sacrificial layer 502 can be completely removed in the unexpanded portions 408-2 of transistor holes 408. The portion of the sacrificial layer 502 that remains in the channel holes 408-1 can act as a protective cover for the channel material inside these portions, while the channel material in the unexpanded portions 408-2 of transistor holes 408 can be exposed due to removal of the sacrificial layer 502. The exposed channel material in the unexpanded portions 408-2 of transistor holes 408 can be then removed, while the channel material in the channel holes 408-1 can remain protected. Therefore, at this point, the channel material in each conductive layer 403 can be isolated from one another. The channel material inside each conductive layer 403 can form a semiconductor body 412. In some implementations, the channel material in the unexpanded portions 408-2 of transistor holes 408 is removed together with the sacrificial layer 502 during one or more same etching processes. In some implementations, the channel material in the unexpanded portions 408-2 of transistor holes 408 is removed after the sacrificial layer 502 has been removed. The removal process can involve one or more dry etching and/or wet etching techniques described herein.

As illustrated in FIG. 5E, the remaining sacrificial layer 502 inside the channel holes 408-1 can be removed to expose the semiconductor body 412. The removal process can involve dry etching and/or wet etching techniques described herein.

Returning to FIG. 4G, after the channel material is partially recessed, a gate dielectric layer 446 can be deposited into the transistor holes 408. In some implementations, gate dielectric layer 446 includes dielectric materials, such as silicon oxide, silicon nitride, or high-k dielectrics including, but not limited to, Al₂O₃, HfO₂, Ta₂O₅, ZrO₂, TiO₂, or any combination thereof. The gate dielectric layer 446 can be deposited using any of the deposition techniques described herein, or any other suitable techniques.

As illustrated in FIG. 4H, a conductive material can be deposited into the transistor holes 408 on the gate dielectric layer 446 to form gate electrode 448. In some implementations, the conductive material of the gate electrode 448 includes, but not limited to W, Co, Cu, Al, TiN, TaN, polysilicon, silicide, or any combination thereof. In some implementations, the gate electrode 448 includes multiple conductive layers, such as a W layer over a TiN layer. The gate electrode 448 can be deposited using any of the deposition techniques described herein, or any other suitable techniques.

As illustrated in FIG. 4I, a polishing process can be performed to remove the conductive material of the gate electrode 448, the gate dielectric layer 446 and the channel material on top of the initial stack 401. The polishing process can involve chemical mechanical polishing (CMP)), wet etching, dry etching, or any combination thereof.

As illustrated in FIG. 4J, at least one capacitor trench 418 can be etched. The capacitor trench 418 can extend into the initial stack 401 vertically along Z direction. In some implementations, the capacitor trench 418 extends across one or more isolation structures 450 along Y direction, as shown in FIG. 4J. The capacitor trench 418 can have a rectangular cross-sectional shape in X-Y plane.

In some implementations, although not shown, the capacitor trench can be located between adjacent isolation structures 450 and does not extend across any isolation structure 450 (e.g., to form the semiconductor device 300, 390 of FIGS. 3A-3E). In the example implementation where the capacitor trench is located between adjacent isolation structures, the capacitor trench can have a circular cross-sectional shape in the X-Y plane, as illustrated in FIGS. 3A-3E.

In some implementations, the at least one capacitor trench 418 is formed between transistor holes 408 along X direction. The formation of the capacitor trench 418 can involve one or more dry etching and/or wet etching techniques described herein.

As illustrated in FIG. 4K, through the capacitor trench 418, a part of the conductive layer 403 that is surrounding the capacitor trench 418 can be recessed. The expanded capacitor trench 418 in the conductive layer 403 can extend close to the semiconductor bodies 412, but without affecting the integrity of the semiconductor bodies 412. The expansion of the capacitor trench 418 can involve one or more dry etching and/or wet etching techniques described herein.

As illustrated in FIG. 4L, a first electrode 422 of the capacitor 420 can be deposited into the capacitor trench 418. Subsequently, the portion of the first electrode 422 that is in the insulating layers 402 can be removed to separate adjacent first electrodes 422 along Z direction. The process steps to recess the portion of the first electrode 422 can be similar to the process described above in reference to FIGS. 5A-5E.

As illustrated in FIGS. 4M and 4N, a capacitor dielectric layer 426 can be deposited on the first electrode 422 of the capacitor 420, and a second electrode 424 of the capacitor 420 can be deposited on the capacitor dielectric layer 426 to form the capacitors 420. In some implementations, capacitor dielectric layer 426 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, first electrode 422 and second electrode 424 include a conductive material including, but not limited to W, Co, Cu, Al, TiN, TaN, polysilicon, silicide, or any combination thereof. In some implementations, the first and second electrodes includes multiple conductive layers, such as a W layer over a TiN layer. The initial stack 401 can become a stack 431 that has alternating insulating layers 402 and memory layers 404. Each memory layer 404 has a plurality of memory cells. The stack 431 can be the stack 201 of FIGS. 2A-2F or the stack 301 of FIGS. 3A-3E.

As illustrated in FIG. 4O, BL contact structures 470 can be formed that extend into the stack 431 at different depths to connect to the bit lines 430 at corresponding memory layers 404. As noted above in reference to FIGS. 2A and 2G, two or more BL contact structures 470 can be coupled to the same bit line 430, and the BL contact structures 470 for each bit line 430 can be arranged in a symmetric manner.

The example fabrication process shown in FIGS. 4A-5E may be applicable with any other implementations of the semiconductor device described herein, e.g., the semiconductor device 290, 300, 390. To fabricate the semiconductor device 300, 390 of FIGS. 3A-3E, the capacitor trench 418 can be formed without extending across any isolation structure 450, as noted above in reference to FIG. 4J. In the example implementation where the capacitor trench is located between adjacent isolation structures, the capacitor trench can have a circular cross-sectional shape in the X-Y plane, as illustrated in FIGS. 3A-3E.

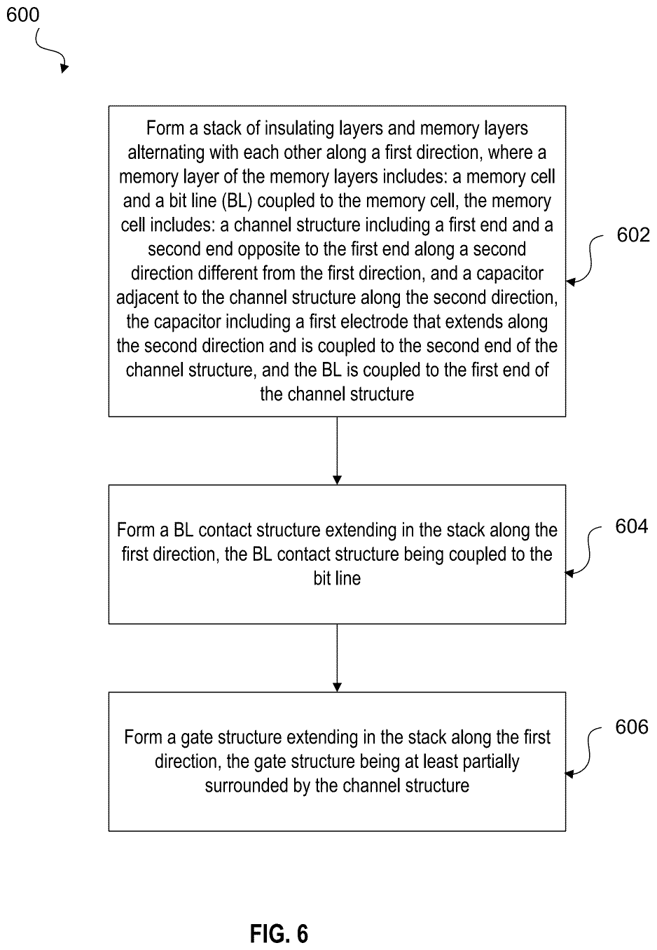

FIG. 6 illustrates a flow chart of a process of an example method 600 to form a semiconductor device. The semiconductor device can be, e.g., the first semiconductor structure 102 of FIG. 1A, the semiconductor device 200 of FIGS. 2A-2F, the semiconductor device 290 of FIG. 2G, the semiconductor device 300 of FIGS. 3A-3D, the semiconductor device 390 of FIG. 3E, or the semiconductor device 400 of FIGS. 4A-5E.

At step 602, a stack of insulating layers and memory layers alternating with each other along a first direction is formed. A memory layer of the memory layers includes: a memory cell and a bit line (BL) coupled to the memory cell. The memory cell includes: a semiconductor body including a first end and a second end opposite to the first end along a second direction different from the first direction, and a capacitor adjacent to the semiconductor body along the second direction. The capacitor includes a first electrode that extends along the second direction and is coupled to the second end of the semiconductor body, and the BL is coupled to the first end of the semiconductor body. The stack can be, e.g., the stack 201 of FIGS. 2A-2G, the stack 301 of FIGS. 3A-3E, or the stack 431 of FIGS. 4N-4O. The insulating layers can be, e.g., the insulating layers 202 of FIGS. 2A-2G, the insulating layers 302 of FIGS. 3A-3E, or the insulating layers 402 of FIGS. 4A-5E. The memory layers can be, e.g., the memory layers 204 of FIGS. 2A-2G, the memory layers 304 of FIGS. 3A-3E, or the memory layers 404 of FIGS. 4N-4O. The memory cell can be, e.g., the memory cell 210 of FIGS. 2A-2G, the memory cell 310 of FIGS. 3A-3E, or the memory cell 410 of FIGS. 4N-4O. The semiconductor body can be, e.g., the semiconductor body 212 of FIGS. 2A-2G, the semiconductor body 312 of FIGS. 3A-3E, or the semiconductor body 412 of FIGS. 4E-4O. The first end of the semiconductor body can be, e.g., the first end 212a of the semiconductor body 212 of FIG. 2C. The second end of the semiconductor body can be, e.g., the second end 212b of the semiconductor body 212 of FIG. 2C. The capacitor can be, e.g., the capacitor 220 of FIGS. 2A-2G, the capacitor 320 of FIGS. 3A-3E, or the capacitor 420 of FIGS. 4N-4O. The first electrode can be, e.g., the first electrode 222 of FIGS. 2A-2G, the first electrode 322 of FIGS. 3A-3E, or the first electrode 422 of FIGS. 4L-4O. The BL can be, e.g., the BL 230 of FIGS. 2A-2G, the BL 330 of FIGS. 3A-3E, or the BL 430 of FIGS. 4A-5E.

At step 604, a BL contact structure is formed extending in the stack along the first direction. The BL contact structure is coupled to the bit line. The BL contact structure can be, e.g., the BL contact structure 270 of FIGS. 2A-2G, the BL contact structure 370 of FIGS. 3A-3E, or the BL contact structure 470 of FIG. 4O.

At step 606, a gate structure is formed extending in the stack along the first direction. The gate structure is at least partially surrounded by the semiconductor body. The gate structure can be, e.g., the gate structure 240 of FIGS. 2A-2G, the gate structure 340 of FIGS. 3A-3E, or the gate structure 440 of FIGS. 4H-4O.

In some implementations, the method includes: forming a second electrode, where the second electrode includes: a first portion extending in the stack in the first direction; and a plurality of second portions spaced apart from one another along the first portion in the first direction, and where a second portion of the plurality of second portions includes a first part and a second part on opposite sides of the first portion along the second direction, respectively, and the second portion extends in a corresponding memory layer of the memory layers along the second direction. The second electrode can be, e.g., the second electrode 224 of FIGS. 2A-2G, the second electrode 324 of FIGS. 3A-3E, or the second electrode 424 of FIGS. 4N-4O. The first portion of the second electrode can be, e.g., first portion 221 of the second electrode 224 of FIGS. 2A-2G, the first portion 321 of the second electrode 324 of FIGS. 3A-3E, or the first portion 421 of the second electrode 424 of FIGS. 4N-4O. The second portions of the second electrode can be, e.g., second portions 223 of the second electrode 224 of FIGS. 2A-2G, the second portions 323 of the second electrode 324 of FIGS. 3A-3E, or the second portions 423 of the second electrode 424 of FIGS. 4N-4O. The first part of a second portion of the second electrode can be, e.g., the first part 223a of a second portion 223 of the second electrode 224 of FIG. 2E. The second part of a second portion of the second electrode can be, e.g., the second part 223b of a second portion 223 of the second electrode 224 of FIG. 2E.

In some implementations, the memory layer is a first memory layer, the memory cell is a first memory cell, and the capacitor is a first capacitor, where forming the memory layers includes forming the first memory layer and a second memory layer, where forming the first memory layer includes forming the first memory cell and a second memory cell adjacent to the first memory cell along the second direction, the second memory cell including a second capacitor, where forming the second memory layer includes forming a third memory cell adjacent to the first memory cell along the first direction, the third memory cell including a third capacitor, each of the second capacitor and the third capacitor including a respective first electrode, and where forming the second electrode includes forming the second electrode such that the respective first electrode of each of the first memory cell, the second memory cell and the third memory cell is at least partially surrounding a corresponding second portion of the plurality of second portions of the second electrode. The first memory layer can be, e.g., the second memory layer 204-2 of FIGS. 2A-2D. The second memory layer can be, e.g., the first memory layer 204-1 of FIGS. 2A-2D. The first memory cell can be, e.g., the first memory cell 210-1 of FIGS. 2B-2D. The second memory cell can be, e.g., the second memory cell 210-2 of FIGS. 2B-2D. The third memory cell can be, e.g., the fourth memory cell 210-4 of FIGS. 2B-2D.

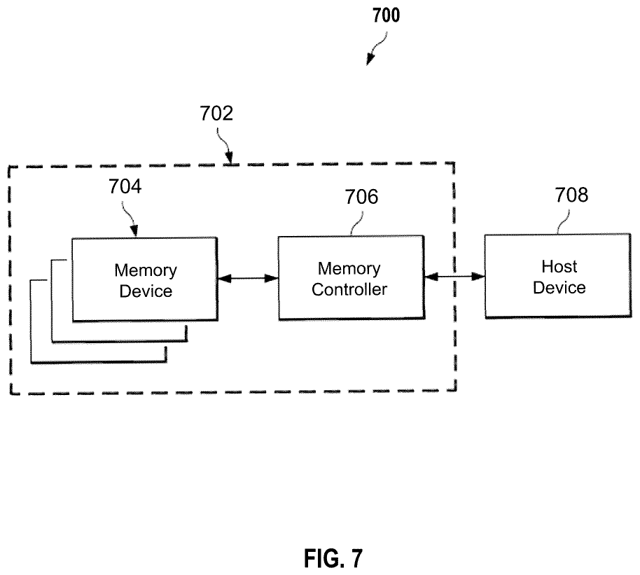

FIG. 7 illustrates a block diagram of a system 700 having one or more semiconductor devices (e.g., memory devices), according to one or more implementations of the present disclosure. The system 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 7, the system 700 can include a host device 708 and a memory system 702 having one or more 3D memory devices 704 and a memory controller 706. Host device 708 can include a processor of an electronic device, such as a central processing unit (CPU), or a system-on-chip (SoC), such as an application processor (AP). Host device 708 can be configured to send or receive data to or from the one or more 3D memory devices 704.

A 3D memory device 704 can be any 3D memory device disclosed herein, such as the first semiconductor structure 102 of FIG. 1A, the semiconductor device 200 of FIGS. 2A-2F, the semiconductor device 290 of FIG. 2G, the semiconductor device of FIGS. 3A-3D, the semiconductor device 390 of FIG. 3E, or the semiconductor device 400 of FIGS. 4A-5E.

In some implementations, a 3D memory device 704 includes a NAND Flash memory. Memory controller 706 (a.k.a., a controller circuit) is coupled to 3D memory device 704 and host device 708. Consistent with implementations of the present disclosure, 3D memory device 704 can include a plurality of conductive interconnections through a cover layer that are in contact with conductive pads in a conductive pad layer, and memory controller 706 can be coupled to 3D memory device 704 through at least one of the plurality of conductive interconnections. Memory controller 706 is configured to control 3D memory device 704. For example, memory controller 706 may be configured to operate a plurality of semiconductor bodies 412 via word lines. Memory controller 706 can manage data stored in 3D memory device 704 and communicate with host device 708.

In some implementations, memory controller 706 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 706 can be configured to control operations of 3D memory device 704, such as read, erase, and program (or write) operations. Memory controller 706 can also be configured to manage various functions with respect to the data stored or to be stored in 3D memory device 704 including, but not limited to bad-block management, garbage collection, logical-to-physical address conversion, wear leveling, etc. In some implementations, memory controller 706 is further configured to process error correction codes (ECCs) with respect to the data read from or written to 3D memory device 704. Any other suitable functions may be performed by memory controller 706 as well, for example, formatting 3D memory device 704.

Memory controller 706 can communicate with an external device (e.g., host device 708) according to a particular communication protocol. For example, memory controller 706 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 706 and one or more 3D memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 7, memory controller 706 and a single 3D memory device 704 may be integrated into a memory card 702. Memory card 702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell 310 transistors 260 (referred to herein as “memory strings,” such as NAND strings) on a laterally-oriented substrate so that the memory strings extend in the vertical direction with respect to the substrate.

As used herein, the term “surrounded by” refers to at least partially surrounded by. For example, A is surrounded by B can refer to that A is at least partially surrounded by B.

As used herein, the term “and/or” as used herein refers to and encompasses any and all possible combinations of one or more of the associated listed terms. For example, the term “A and/or B” means that either option A, option B, or both options A and B are possible, where A and B may be singular or plural.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a stack of insulating layers and memory layers alternating with each other along a first direction, a memory layer of the memory layers comprises:
a memory cell including:
a semiconductor body including a first end and a second end opposite to the first end along a second direction different from the first direction; and
a capacitor structure adjacent to the semiconductor body along the second direction, the capacitor structure comprising a first electrode that extends along the second direction and is coupled to the second end of the semiconductor body; and
a bit line (BL) coupled to the first end of the semiconductor body; and
a gate structure extending in the stack along the first direction, the gate structure being at least partially surrounded by the semiconductor body.

2. The semiconductor device of claim 1, comprising:
a second electrode including:
a first portion extending in the stack in the first direction; and
a plurality of second portions spaced apart from one another along the first portion in the first direction,
wherein a second portion of the plurality of second portions comprises a first part and a second part on opposite sides of the first portion along the second direction, respectively, and the second portion extends in a corresponding memory layer of the memory layers along the second direction.

3. The semiconductor device of claim 2, wherein:
the memory cell is a first memory cell, the semiconductor body is a first semiconductor body, the capacitor structure is a first capacitor structure;
the memory layer comprises a second memory cell including a second semiconductor body coupled to the bit line and a second capacitor structure; and
the first capacitor structure and the second capacitor structure are between the first semiconductor body and the second semiconductor body along the second direction.

4. The semiconductor device of claim 3, wherein:
the second capacitor structure comprises a respective first electrode, the first electrode of each of the first capacitor structure and the second capacitor structure is coupled to the second electrode and is separated from the second electrode by a capacitor dielectric layer; and
the first electrode of the first capacitor structure is at least partially surrounding the first part of a corresponding second portion of the plurality of second portions of the second electrode, and the first electrode of the second capacitor structure is at least partially surrounding the second part of the corresponding second portion of the plurality of second portions of the second electrode.

5. The semiconductor device of claim 2, comprising:
an isolation structure extending in the stack along the first direction and the second direction,
wherein the memory cell is a first memory cell, the memory layer comprises a third memory cell adjacent to the first memory cell along a third direction different from the first direction and the second direction, the first memory cell and the third memory cell are separated by the isolation structure along the third direction, and the third memory cell comprises a third semiconductor body and a third capacitor structure.

6. The semiconductor device of claim 5, wherein:
the first portion of the second electrode extends through the isolation structure along the third direction,
the second portion of the plurality of second portions of the second electrode further comprises a third part and a fourth part on opposite sides of the first portion along the second direction, respectively, the third part is adjacent to the first part and separated from the first part by the isolation structure along the third direction, and the fourth part is adjacent to the second part and separated from the second part by the isolation structure along the third direction, and
the third capacitor structure comprises a respective first electrode coupled to the second electrode, and the first electrode of the third capacitor structure is at least partially surrounding the third part of the second portion of the plurality of second portions of the second electrode.

7. The semiconductor device of claim 5, comprising:
a plurality of second electrodes including the second electrode,
wherein first portions of adjacent second electrodes of the plurality of second electrodes that arranged along the third direction is separated by the isolation structure.

8. The semiconductor device of claim 1, wherein:
the bit line comprises a first segment extending along a third direction different from the first direction and the second direction.

9. The semiconductor device of claim 8, wherein the bit line comprises at least one of:
a second segment extending along the second direction and being coupled to a first end the first segment; or
a third segment extending along the second direction and being coupled to a second end of the first segment, the second end of the first segment being opposite to the first end of the first segment along the third direction.

10. The semiconductor device of claim 9, comprising:
a BL contact structure extending in the stack along the first direction; and
wherein the BL contact structure is in contact with one of the first segment, the second segment or the third segment of the bit line.

11. The semiconductor device of claim 9, comprising:
a plurality of BL contact structures including a first BL contact structure and a second BL contact structure;
the second segment comprises a first end coupled to the first end of the first segment, the third segment comprises a first end and a second end, the first end of the third segment coupled to the second end of the first segment, the second end of the third segment opposite to the first end of the third segment along the second direction; and
the first BL contact structure is in contact with the first end of the second segment, and the second BL contact structure is in contact with the second end of the third segment.

12. The semiconductor device of claim 1, wherein the gate structure comprises:
a first portion extending in the stack in the first direction; and
a plurality of second portions spaced apart from one another along the first portion of the gate structure in the first direction,
wherein a width of the first portion of the gate structure along a third direction different from the first direction and the second direction is smaller than a width of a second portion of the plurality of second portions of the gate structure along the third direction.

13. The semiconductor device of claim 12, wherein the semiconductor body of the memory cell comprises two opposing walls along the first direction and a sidewall connecting the two opposite walls, the two opposing walls and the sidewall define an internal opening,
wherein a corresponding second portion of the plurality of second portions of the gate structure is at least partially within the internal opening of the semiconductor body of the memory cell.

14. The semiconductor device of claim 1, wherein the semiconductor body has a first width along the second direction and a second width along a third direction different from the first direction and the second direction, and the first width of the semiconductor body is greater than the second width of the semiconductor body.

15. A semiconductor device, comprising:
a stack of insulating layers and memory layers alternating with each other along a first direction, the memory layers comprising a first memory layer and a second memory layer, the first memory layer comprising a first memory cell and a second memory cell adjacent to the first memory cell along a second direction different from the first direction, the second memory layer comprising a third memory cell adjacent to the first memory cell along the first direction,
wherein each of the first memory cell, the second memory cell and the third memory cell comprises:
a semiconductor body; and
a capacitor structure adjacent to the semiconductor body along the second direction, the capacitor structure extending along the second direction and being coupled to the semiconductor body, the capacitor structure including a first electrode,
wherein the capacitor structure of the first memory cell and the capacitor structure of the second memory cell are between the semiconductor body of the first memory cell and the semiconductor body of the second memory cell along the second direction; and
a second electrode extending in the stack along the first direction and being coupled to the first electrode of each of first memory cell, the second memory cell and the third memory cell.

16. The semiconductor device of claim 15, wherein:
the first memory layer comprises a first bit line (BL) coupled to the first memory cell and the second memory cell, and the second memory layer comprises a second bit line coupled to the third memory cell; and
the semiconductor device comprises a plurality of BL contact structures extending in the stack at different depths, and the plurality of BL contact structures comprises:
a first BL contact structure coupled to the first bit line of the first memory layer; and
a second BL contact structure coupled to the second bit line of the second memory layer.

17. The semiconductor device of claim 15, comprising:
a plurality of gate structures extending in the stack along the first direction,
wherein the plurality of gate structures comprises:
a first gate structure at least partially surrounded by the semiconductor body of the first memory cell and the semiconductor body of the third memory cell; and
a second gate structure at least partially surrounded by the semiconductor body of the second memory cell.

18. A method, comprising:
forming a stack of insulating layers and memory layers alternating with each other along a first direction, wherein a memory layer of the memory layers comprises: a memory cell and a bit line (BL) coupled to the memory cell, the memory cell includes: a semiconductor body including a first end and a second end opposite to the first end along a second direction different from the first direction, and a capacitor structure adjacent to the semiconductor body along the second direction, the capacitor structure comprising a first electrode that extends along the second direction and is coupled to the second end of the semiconductor body, and the BL is coupled to the first end of the semiconductor body; and
forming a gate structure extending in the stack along the first direction, the gate structure being at least partially surrounded by the semiconductor body.

19. The method of claim 18, comprising: forming a second electrode,
wherein the second electrode comprises:
a first portion extending in the stack in the first direction; and
a plurality of second portions spaced apart from one another along the first portion in the first direction, and
wherein a second portion of the plurality of second portions comprises a first part and a second part on opposite sides of the first portion along the second direction, respectively, and the second portion extends in a corresponding memory layer of the memory layers along the second direction.

20. The method of claim 19, wherein the memory layer is a first memory layer, the memory cell is a first memory cell, and the capacitor structure is a first capacitor structure,
wherein forming the memory layers comprises forming the first memory layer and a second memory layer,
wherein forming the first memory layer comprises forming the first memory cell and a second memory cell adjacent to the first memory cell along the second direction, the second memory cell comprising a second capacitor structure,
wherein forming the second memory layer comprises forming a third memory cell adjacent to the first memory cell along the first direction, the third memory cell comprising a third capacitor structure, each of the second capacitor structure and the third capacitor structure comprising a respective first electrode, and
wherein forming the second electrode comprises forming the second electrode such that the respective first electrode of each of the first memory cell, the second memory cell and the third memory cell is at least partially surrounding a corresponding second portion of the plurality of second portions of the second electrode.
